(19) United States
(12) Patent Application Publication
(10) Pub. No.: US 2021/0294406 A1
(43) Pub. Date: Sep. 23, 2021

(54) DATACENTER POWER MANAGEMENT USING CURRENT INJECTION

(71) Applicant: Virtual Power Systems, Inc., Milpitas, CA (US)

(72) Inventors: Craig Broadbent, Lake Geneva, WI (US); Clark A. Jeria Frias, San Jose, CA (US); Karimulla Raja Shaikh, Cupertino, CA (US); Ohannes Wanes, Richmond Hill (CA)

(73) Assignee: Virtual Power Systems, Inc., Milpitas, CA (US)

(21) Appl. No.: 17/206,186

(22) Filed: Mar. 19, 2021

Related U.S. Application Data
(60) Provisional application No. 63/147,254, filed on Feb. 9, 2021.
(60) Provisional application No. 63/119,003, filed on Nov. 30, 2020.
(60) Provisional application No. 63/084,597, filed on Sep. 29, 2020.
(60) Provisional application No. 63/052,476, filed on Jul. 16, 2020.
(60) Provisional application No. 63/039,000, filed on Jun. 15, 2020.
(60) Provisional application No. 62/992,186, filed on Mar. 20, 2020.

(51) Int. Cl. G06F 1/3228; G06F 1/28

(52) U.S. Cl. CPC G06F 1/3228; G06F 1/28

(57) ABSTRACT

Datacenter power management using current injection is disclosed. A datacenter topology that includes a utility grid feed, power caches, power control blocks, loads, and uninterruptible power supplies (UPSs) providing AC power is accessed. A supply capacity is allocated from a first UPS to the one or more loads within the datacenter, below a peak load requirement for the loads. It is also allocated based on a datacenter power policy. An AC current requirement is detected by the one or more power control blocks. The AC current requirement is detected for the one or more loads at the output network of the first UPS. AC current is injected into the output network of the first UPS by the one or more power control blocks. The AC current injection is based on the AC current requirement that was detected. The AC current injection is further based on the datacenter power policy.

### RELATED APPLICATIONS

This application claims the benefit of U.S. provisional patent applications “Datacenter Power Management Using Current Injection” Ser. No. 62/992,186, filed Mar. 20, 2020, “Datacenter Current Injection For Power Management” Ser. No. 63/052,476, filed Jul. 16, 2020, “Datacenter Power Management Through Phase Balancing” Ser. No. 63/039,000, filed Jun. 15, 2020, “Datacenter Power Management With Edge Block Mediation” Ser. No. 63/084,597, filed Sep. 29, 2020, “Datacenter Power Management Using Adaptive Interfacing” Ser. No. 63/119,003, filed Nov. 30, 2020, and “Datacenter Power Management With Distributed Policy Interaction” Ser. No. 63/147,254, filed Feb. 9, 2021.

Each of the foregoing applications is hereby incorporated by reference in its entirety.

### FIELD OF ART

This application relates generally to power management and more particularly to datacenter power management using current injection.

### BACKGROUND

Organizations with compute-intensive interest conduct processing operations within large-scale computing facilities called datacenters or “server farms.” A datacenter houses a network of heterogeneous systems which are vital to the operation of the organization. The systems can be housed in many rows of data racks containing servers, storage devices, routers, backup equipment, communications units, and other information technology (IT) equipment. The organization uses the datacenter to perform computational operations and to store, process, manage, and disseminate valuable data. Organizational top priorities include ensuring uninterrupted operation of the datacenter and protecting the security and reliability of the information resources. Further, datacenters have large and changeable power requirements. Some of the systems in the datacenter have more stringent power and availability requirements than other systems. Thus, deployment and placement of equipment within a datacenter are critical. The amount of power demanded by and allocated to the data racks is often very high. This power demand produces copious heat which must be removed. Further, the power demand fluctuates based on specific business factors, such as the processing job mix and the time of day, month, or season. Thus, managing power, space, and cooling are paramount concerns. Additionally, energy savings within the datacenter directly translate to increased profit margins, reduced wear and tear on power sources and equipment, and reduced cooling costs.

The computer systems within the datacenter, including circuit boards, mass storage devices, networking interfaces, and processors, all consume power. Given the power requirements of these components, reliable and efficient power delivery is crucial. In fact, the reliability and availability requirements of the datacenter infrastructure must meet or exceed predetermined statutory requirements. Further, statutory requirements dictate standards for protecting customer data which must be upheld by financial institutions, healthcare organizations, educational organizations, and retail organizations. Additional infrastructure requirements address availability, reliability, job load, and other organizational demands. Other datacenter design considerations involve providing sufficient power to the datacenter. Power can be provided by more than one power grid for high-reliability datacenters. Power can be provided by a combination of a power grid and locally generated power. Regardless of how the power is provided, delivering reliable and efficient power is essential.

### SUMMARY

Datacenter operation dictates stringent power requirements. The datacenter power requirements can change greatly over time due to the quantity and mix of datacenter equipment; changes in positioning of racks; changes in cooling requirements; and other electrical, thermal, and deployment factors. Other requirements are based on the mix or combination of the processing jobs. Power requirements are dependent on the loads driven, including AC and DC loads. For example, power requirements can increase during normal business hours, and decrease after-hours and/or on weekends or holidays. Furthermore, the makeup of AC load demand vs. DC load demand can change as equipment in the datacenter is added or swapped out. Less predictable or “soft” factors include scheduling various batch jobs and other processing tasks. The power requirement fluctuations can be influenced by required software or application activity, planned maintenance, unplanned events such as equipment failure, etc.

Disclosed techniques enable datacenter power management using current injection. The current can be injected by power control blocks into an output network of an uninterruptible power supply (UPS). The injecting can maintain a constant voltage and an in-phase AC frequency, that is, it doesn't disturb or perturb the existing voltage magnitude, phase, and frequency while additional current is being provided to the existing output network. A datacenter power policy is developed and implemented. The policy that is implemented can be based on business objectives, statutory requirements, and so on. The policy that is implemented is used to oversee a datacenter topology. The datacenter topology can include at least one utility grid feed, one or more power caches, one or more power control blocks, one or more loads, and one or more uninterruptible power supplies (UPSs) providing AC power. The datacenter topology can further include heating, ventilating, and air conditioning (HVAC) equipment, communication equipment, switches or circuit breakers, and the like. A supply capacity is allocated from a first UPS to the one or more loads within the datacenter. A supply capacity can be based on one or more voltages, current rating, etc. The supply capacity is allocated below a peak load requirement for the one or more loads. The supply capacity can be based on an average level, a contractual level, a seasonal level, etc. The supply capacity is allocated based on the datacenter power policy. An AC current requirement is detected. The AC current requirement can be based on current loads, anticipated or scheduled loads, etc. The detecting can be accomplished by the one or more power control blocks. The AC current requirement corresponds to the one or more loads at the output network of the first UPS. AC current is injected into the output network of the first UPS. The amount of AC current that is injected is used to fill a gap between the allocated supply capacity and the detected AC current requirement. The current is injected by the one or more power control blocks. The injecting is based on the detecting. The injecting is further based on the datacenter power policy that was implemented.

A computer-implemented method for power management is disclosed comprising: accessing a datacenter topology that includes at least one utility grid feed, one or more power caches, one or more power control blocks, one or more loads, and one or more uninterruptible power supplies (UPSs) providing AC power; allocating a supply capacity from a first UPS to the one or more loads within the datacenter topology, wherein the supply capacity is allocated below a peak load requirement for the one or more loads; detecting an AC current requirement, by the one or more power control blocks, for the one or more loads at an output network of the first UPS; and injecting AC current into the output network of the first UPS, by the one or more power control blocks, wherein the injecting is based on the AC current requirement that was detected.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for datacenter power management using current injection.

FIG. 2 is a flow diagram for updating power topology.

FIG. 3 is a block diagram for intelligent control of energy.

FIG. 4 illustrates pulse width modulation (PWM) of a sinusoid.

FIG. 5A is a block diagram of a power control module.

FIG. 5B is a block diagram for power control module usage.

FIG. 6A is a block diagram for a charger.

FIG. 6B is a block diagram for a single-phase inverter.

FIG. 7A shows parallelable energy control with three wire and protective earth.

FIG. 7B shows parallelable energy control with three wire, neutral, and protective earth for wye configuration.

FIG. 7C shows serial energy control with three wire and protective earth.

FIG. 8A illustrates example rack density configurations.

FIG. 8B illustrates a parallel stack configuration.

FIG. 9 shows a datacenter rack configuration.

FIG. 10 illustrates augmented power control using predictive modeling.

FIG. 11 shows a topology representation with multiple sets.

FIG. 12 illustrates hierarchical allocation of power control.

FIG. 13 is a system diagram for datacenter power management using current injection.

### DETAILED DESCRIPTION

This disclosure provides techniques for datacenter power management using current injection. Managing the many information technology (IT) tasks, including the efficiency and reliability of power distribution, space allocation, and cooling capacity, is a highly complex and challenging task. Datacenters pose particularly difficult resource management challenges because the supply of and demand for power must be carefully balanced. Some datacenters are designed for and dedicated to a single organization, while other datacenters provide contracted resources for use by multiple organizations. Use of a given datacenter by various organizations can be managed based on multiple factors. The factors can include the amount of equipment a given organization requires to locate in the datacenter, power load requirements, power source redundancy requirements such as 1N, 1N+1, or 2N redundancy, service level agreements (SLAs) and other contractual obligations for the power, etc. Datacenter power systems are designed to meet the dynamic power needs of large installations of diverse electrical equipment. A wide range of processing and other electrical equipment can be present in a datacenter, including devices such as servers, blade servers, communications switches, backup data storage units, communications hardware, and other devices. The electrical equipment can include one or more of processors; data servers; server racks; and heating, ventilating, and air conditioning (HVAC) units. The HVAC units are installed to manage humidity and the prodigious heat that is dissipated by all of the electrical equipment in the datacenter. The power systems receive power from multiple power feeds, where the coupled power feeds can derive from grid power such as hydro, wind, solar, nuclear, coal, or other power plants; local power generated from micro-hydro, wind, solar, geothermal, etc.; diesel-generator (DG) sets; and so on. The multiple power feeds, typically numbering at least two feeds, provide critical redundancy for power delivery to the datacenter power system. That is, if one power feed were to go down or be taken offline for maintenance, then another power feed can provide the dynamic power needed to drive the power load of the datacenters without interruption. In modern datacenters, the infrastructure within a datacenter can be controlled by software. The use of software defined IT infrastructures, such as compute, network, or storage infrastructures, supports flexible and automated management of datacenter power. Many different datacenter structures and business models, including enterprise datacenters, colocation datacenters, hyperscale datacenters, brownfield datacenters, greenfield datacenters, microgrid datacenters, modularized datacenters, cloud processing datacenters, and so on, can be enhanced by the techniques disclosed within.

In disclosed techniques, power management within a datacenter is based on datacenter power management using current injection. A datacenter power policy is determined, developed, and implemented, where the policy oversees a datacenter topology. The datacenter policy can be based on measured capacity, on anticipated power loads, on contractual agreements, and so on. The datacenter topology can include at least one utility grid feed, one or more power caches, one or more power control blocks, one or more loads, and one or more uninterruptible power supplies (UPSs) providing AC power. A supply capacity from a first UPS is allocated to the one or more loads within the datacenter. The allocating can be based on measured load, anticipated load, contracted load, etc. The supply capacity is allocated below a peak load requirement for the one or more loads, and is further allocated based on the datacenter power policy. An AC current requirement is detected by the one or more power control blocks. The current requirement can be based on processing and other electrical equipment requirements, job mixes, and the like. The current requirement is detected for the one or more loads at the output network of the first UPS. AC current is injected into the output network of the first UPS, by the one or more power control blocks, based on the detecting and the datacenter power policy. The injecting does not disturb a voltage supplied by an upstream source or a phase of AC frequency supplied by an upstream source. The injecting can further include injecting AC current into the output network of a second UPS of the one or more UPSs. In embodiments, at least one of the one or more uninterruptible power supplies is operated in pass-through mode. In pass-through mode, the UPS is not enabled to provide uninterruptible power, but rather simply provides input source power at its output(s).

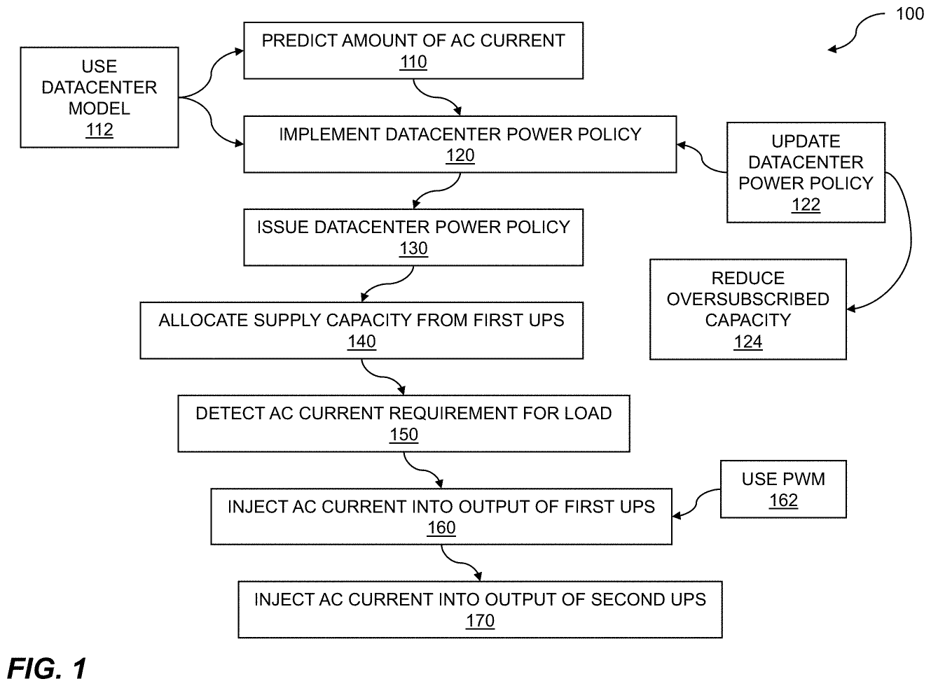

FIG. 1 is a flow diagram for datacenter power management using current injection. The amount and type of power provided to IT equipment within a datacenter can be based on contractual agreements, available power sources, available backup power sources, job mix, job scheduling, and so on. The flow 100 shows a computer-implemented method for power management. The flow 100 includes predicting an amount of AC current 110 for injecting into the output network. The predicting can be based on data, where the data can include collected usage data, historical data, anticipated usage requirements or estimations, and so on. In embodiments, the predicting can be performed using a software-based datacenter model 112. The software-based datacenter model can include a predictive model for current usages by equipment throughout the datacenter. The predictive model can include a power prediction model, where the power prediction model can include predicted power usage and a power correlation model. The power prediction model can be used to predict power usage requirements by the IT and electrical equipment at a time subsequent to the time at which the prediction model was calculated. The power prediction model can be updated, changed, replaced, refined, and so on, by correlating predicted power usage with measured power usage.

The flow 100 includes implementing a datacenter power policy 120. The datacenter power policy can include the datacenter model. The datacenter power policy controls or oversees a datacenter topology, where the datacenter topology can include power sources, power distribution, power loads, and the like. In embodiments, the one or more loads within the datacenter topology can be mission critical loads. The topology provides for the connection of power to one or more data racks within the datacenter. In embodiments, the datacenter topology can provide a series connection from a first UPS to two or more datacenter racks. Other connection strategies may also be used. In other embodiments, the datacenter topology can provide a parallel connection from the first UPS to two or more datacenter racks. The power sources can include utility power sources and local power feed components. The local power feed components can include locally generated power, power control blocks, power caches which can include batteries or capacitors, etc., switches or breakers, power distribution units, and so on. The local power feed components can include renewable power sources. In embodiments, the datacenter topology can include at least one utility grid feed, one or more power caches, one or more power control blocks, one or more loads, and one or more uninterruptible power supplies (UPSs) providing AC power. The datacenter topology can include power distribution and usage, power switching, power monitoring, etc. More than one datacenter power policy can be developed and implemented. In a usage example, a first datacenter power policy can be implemented for normal or contracted operations, a second datacenter power policy can be implemented for emergency operations, and so on. The datacenter power policy can be implemented using software. The power policy software can interrogate various components of the datacenter topology, power sources and power loads, power caches, power control points, etc. Data collected by the interrogation can be analyzed to form the power policy.

The flow 100 further includes updating the datacenter power policy 122, based on additional source and load data. The updating the power policy can be based on analyzing data collected from power sources, power loads, etc. In embodiments, the updating can include reducing oversubscribed capacity 124 within the datacenter topology. Data collected that relates to power usage based on actual loads can be used to reduce the allocated power capacity. In further embodiments, the updating can improve utilization, improve datacenter return on investment (ROI), etc. The updating can be accomplished periodically such as based on a schedule, opportunistically such as during an activity minimum within the datacenter, etc. In embodiments, the updating can be accomplished dynamically.

The flow 100 includes issuing the datacenter power policy 130 to individual hardware components within a datacenter topology. The issuing can be accomplished using wired or wireless communication techniques. The issuing the datacenter power policy can occur on a private network or other network within the datacenter. The issuing the datacenter power policy can include issuing the policy in an encrypted format. The issuing the policy can include issuing the policy to processing equipment, electrical equipment, switching equipment, and so on. In embodiments, the hardware components can include the one or more power control blocks. The issuing the policy can accomplish a variety of power management objectives. In embodiments, the issuing can enable the individual hardware components to inject current into the output network, based on the datacenter power policy. The issuing can comprise implementing the datacenter power policy, although other ways of implementing the policy can exist, such as having a static or hardcoded policy. The injecting current is discussed shortly. The flow 100 includes allocating a supply capacity from a first UPS 140 to the one or more loads within the datacenter. The allocating the supply capacity can be based on an estimated load, a contracted load, a load based on historical load or usage data, and so on. The allocating the supply capacity can be based on a target value, a threshold, etc. In embodiments, the supply capacity is allocated below a peak load requirement for the one or more loads. The supply capacity is allocated based on the datacenter power policy. The flow 100 includes detecting an AC current requirement 150, by the one or more power control blocks, for the one or more loads at the output network of the first UPS. The detecting an AC current requirement can include an instantaneous current (dI/dt), an average current, an RMS current, a peak current, and the like. The detecting can be accomplished using one or more current detectors. The current detectors can be located within a main power panel, a remote power panel positioned adjacent to processing or electrical equipment, etc. In embodiments, a power control block provides data collection for power system current, voltage, and/or power.

The flow 100 includes injecting AC current into the output network of the first UPS 160. The output network of the first UPS 160 comprises an upstream source for the datacenter node being supplied by the injecting AC current. The injecting can be accomplished by the one or more power control blocks. The injecting is based on the detecting and the datacenter power policy. The power control blocks can access energy stored in one or more power caches. The power caches can be based on various types of rechargeable components such as sealed lead acid (SLA) batteries, lithium iron phosphate (LiFePO4) batteries, etc. The power caches can be based on capacitors, super capacitors, and the like. The injecting of AC current into the output network for the first UPS can be implemented using various techniques including modulation techniques. In embodiments, the injecting is controlled using pulse width modulation (PWM) 162. The PWM can be accomplished using one or more circuit topologies. In embodiments, the pulse width modulation can be enabled by one or more current mode grid tie inverters. The PWM can be used to connect and disconnect one or more power caches. The width of a pulse can be modulated to adjust an amount of delivered average power. In embodiments, the pulse width modulation is used to control output of at least one of the one or more power caches. The injecting can be performed based on one or more parameters. In embodiments, the injecting does not disturb a voltage supplied by an upstream source. In embodiments, the injecting does not disturb a phase of AC frequency supplied by an upstream source. The power that is injected from the one or more power caches can be obtained using one or more techniques. In embodiments, the allocating, the detecting, and the injecting can accomplish datacenter peak shaving. Peak shaving reduces the source power level for a period of time and may use stored energy from a cache, from a battery control module, and so on. Unused current can be defined as capacity that becomes available when peak shaving is not taking place and source power capacity exceeds load power demand. When peak shaving is not active, it becomes possible to store unallocated energy in a cache.

The flow 100 further includes injecting AC current into the output network of a second UPS 170 of the one or more UPSs. Note that a data rack within a datacenter can be connected to more than one power source. Many power supplies for processors, for example, come equipped with two power cords, one power cord to connect to a first power source and a second power cord to connect to a second power source. In embodiments, the second UPS can be sourced from a different utility grid source from the first UPS. By providing two power sources to the data rack, various management techniques can be implemented, such as balancing loads between the two sources, providing a redundant power source in the event of a power source failure, and so on. In embodiments, the second UPS provides datacenter power redundancy. Various levels of power redundancy can be supported. The power redundancy can include 1N redundancy, where there are no spare power sources; 1N+1 redundancy, where there is one spare power source, 2N redundancy where there is a spare power source for each power source, and the like.

Various embodiments of the flow 100 can be included in a computer program product embodied in a non-transitory computer readable medium that includes code executable by one or more processors.

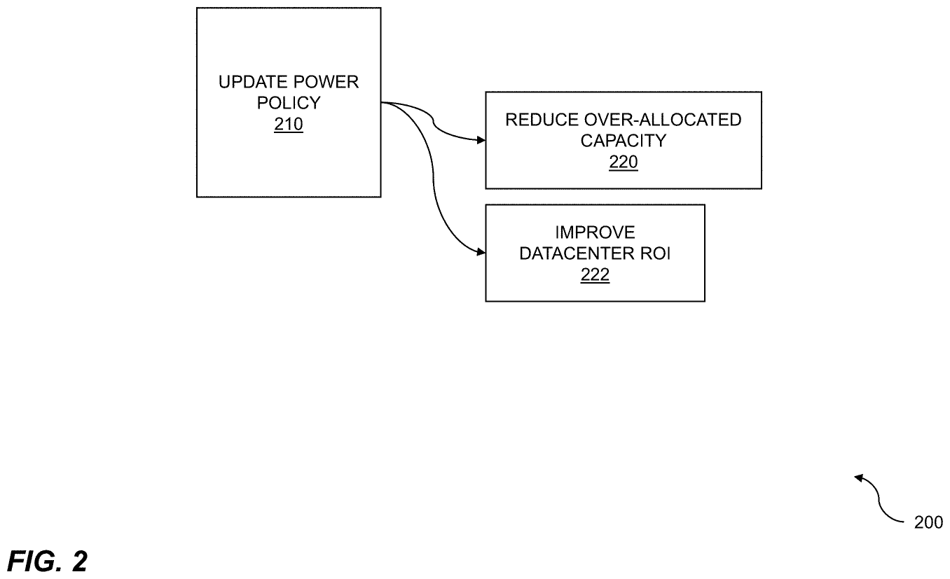

FIG. 2 is a flow diagram for updating power topology. Presented throughout, a datacenter power policy can be implemented to oversee a datacenter topology. The datacenter power policy need not remain static. Rather, the datacenter power policy can be modified, updated, redeveloped, restructured, and so on. The updating of the power policy, for example, can result from changes to processor configurations or to other electrical equipment within the datacenter, updates to statutory requirements, new or modified contractual obligations, and the like. Updating the power topology of the datacenter supports datacenter power management using current injection. A datacenter power policy is implemented, where the policy oversees a datacenter topology. A supply capacity is allocated from a first UPS to the one or more loads within the datacenter. The supply capacity is allocated below a peak load requirement for the one or more loads. An AC current requirement is detected by the one or more power control blocks. The AC current requirement is detected for the one or more loads at the output network of the first UPS. AC current is injected into the output network of the first UPS, by the one or more power control blocks, based on the detecting and the datacenter power policy.

The allocating a supply capacity from a UPS and the injecting AC current into the output network of the UPS are based on a datacenter power policy. Changes to the datacenter power policy can be required when the mix of processing equipment changes; when electrical equipment within the datacenter is removed, added, or updated; and so on. The datacenter power policy can further require adjustment based on collection of operational data, historical data, etc. The flow 200 can include updating the datacenter power policy 210 based on additional source and load data. Data can be collected from one or more processing components, electrical equipment, power distribution components, and the like, throughout the datacenter. Data can also be collected based on the datacenter topology. The data can be collected continuously, intermittently, etc. The data can be analyzed to determine whether the datacenter power policy is supporting the operational efficiency of the datacenter.

In the flow 200, the updating can include reducing over-allocated capacity 220 within the datacenter. Allocating a supply capacity from a grid line source, an alternative energy source, a UPS, a power cache, etc., is a difficult task because actual AC current requirements can differ, greatly at times, from supply capacity allocations. By collecting data regarding the detected AC current requirements, the current allocations can be tuned or adjusted to better meet requirements. In embodiments, the updating can improve utilization. The improvement of utilization can include increasing capacity based on job mixes of seasonal requirements, reducing capacity based on historical data or contractual obligations, etc. In the flow 200, the updating can improve datacenter ROI 222. ROI can be improved by operating datacenter processing and electrical equipment efficiently from an operational standpoint, reducing overutilization of some equipment while increasing use of underutilized equipment, and the like. In embodiments, the updating can be accomplished dynamically.

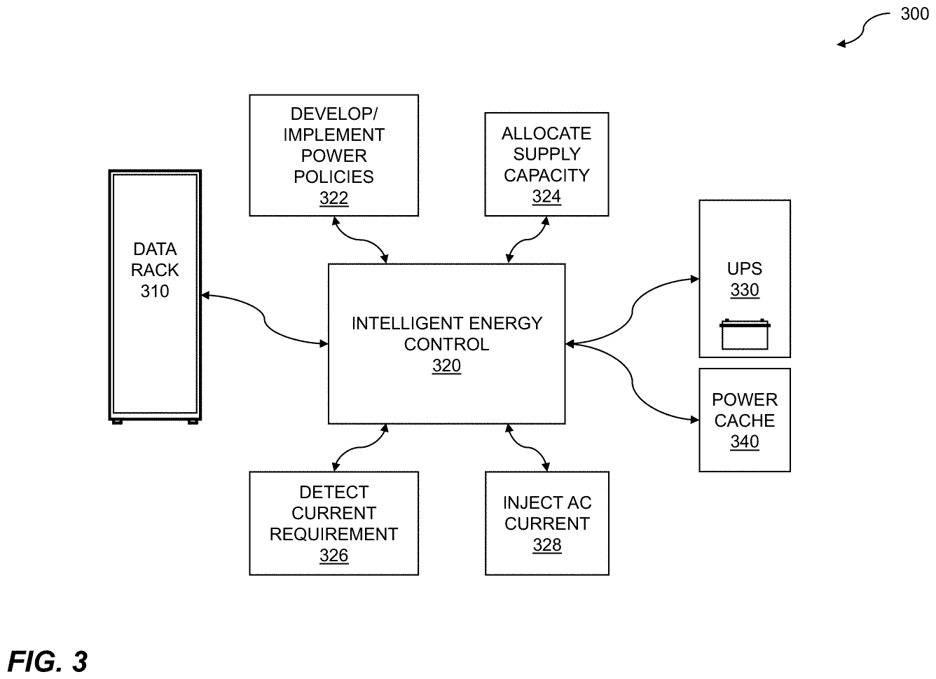

FIG. 3 is a block diagram for intelligent control of energy 300. Power management within a datacenter can be based on intelligent control of energy. Intelligent control of energy, which can include both AC energy and DC energy, enables datacenter power management using current injection. A datacenter power policy is implemented, where the policy oversees a datacenter topology that includes at least one utility grid feed, power caches, power control blocks, loads, and uninterruptible power supplies (UPSs) providing AC power. A supply capacity from a first UPS is allocated to the loads within the datacenter, where the supply capacity is allocated below a peak load requirement for the loads, and where the supply capacity is allocated based on the datacenter power policy. An AC current requirement is detected, by the power control blocks, for the loads at the output network of the first UPS. AC current is injected into the output network of the first UPS, by the power control blocks, based on the detecting and the datacenter power policy.

Intelligent energy control can include a datacenter power policy. The datacenter power policy, which can be based on processing and electrical equipment within a datacenter, usage requirements, contractual obligations, and so on, can be used to control power consumption by processors or electrical equipment, to prioritize allocation of power to equipment, to schedule processing tasks, and so on. Intelligent energy control can include communication with equipment within the datacenter in order to manage that equipment. The communication can include connecting to the various items of electrical equipment; collecting status, state, and other data from the electrical equipment; and controlling the electrical equipment. The electrical equipment can include processors, servers, communication equipment, backup, and storage; power distribution equipment; cooling equipment, etc. The type of equipment and the capabilities of the equipment to be controlled can determine the level of intelligent energy control of the equipment. Some equipment within the datacenter can be controlled by policies that can be loaded onto the equipment. This equipment can support intelligent control. Equipment that can be controlled locally using intelligent control can comprise compatible components, where the compatible components can include compatible power distribution units (PDUs), compatible uninterruptable power supplies (UPSs), compatible electrical distribution switch gear, etc. Other equipment or components within the datacenter cannot be controlled locally using intelligent control, but can be controlled centrally by intelligent energy control. This latter type of equipment can support direct control. These other components can include other PDUs, other UPSs, other switch gears, and so on. Further equipment within the datacenter can be controlled by intelligent energy control. This further equipment can comprise infrastructure management, where infrastructure management can include HVAC management, facilities management, IT server management, and so on.

A data rack 310 can contain processors, servers, communication equipment, and so on, where the equipment within the data rack can be operated, adjusted, manipulated, and so on by intelligent energy control 320. Intelligent energy control can include turning on and off electrical equipment such as servers, blade servers, data servers, communication equipment, etc.; shifting virtual machines to slower processers to reduce power consumption; slowing processor clock rates of servers or blade servers to reduce power consumption; and the like. The intelligent energy control can be based on developing and implementing one or more power policies 322. A power policy can be used to oversee a datacenter topology. The datacenter topology comprises energy sources such as utility grid power, power caches, power control blocks, UPSs, loads, etc. The intelligent energy control can include allocating a supply capacity 324. The supply capacity can be allocated from a power source, where the power source can include a UPS 330. In embodiments, the supply capacity can be allocated from a power cache 340, where the power cache can include one or more batteries, capacitors, etc. The supply capacity can be allocated below a peak load requirement, below a threshold value, etc. Intelligent energy control can include detecting an AC current requirement 326 for one or more loads. The loads can be at the output network of a UPS. The detecting can be performed by one or more power control blocks. Intelligent energy control can include injecting AC current 328 into a network, where the network can include the output network of the UPS. The injecting can be performed by the power control blocks.

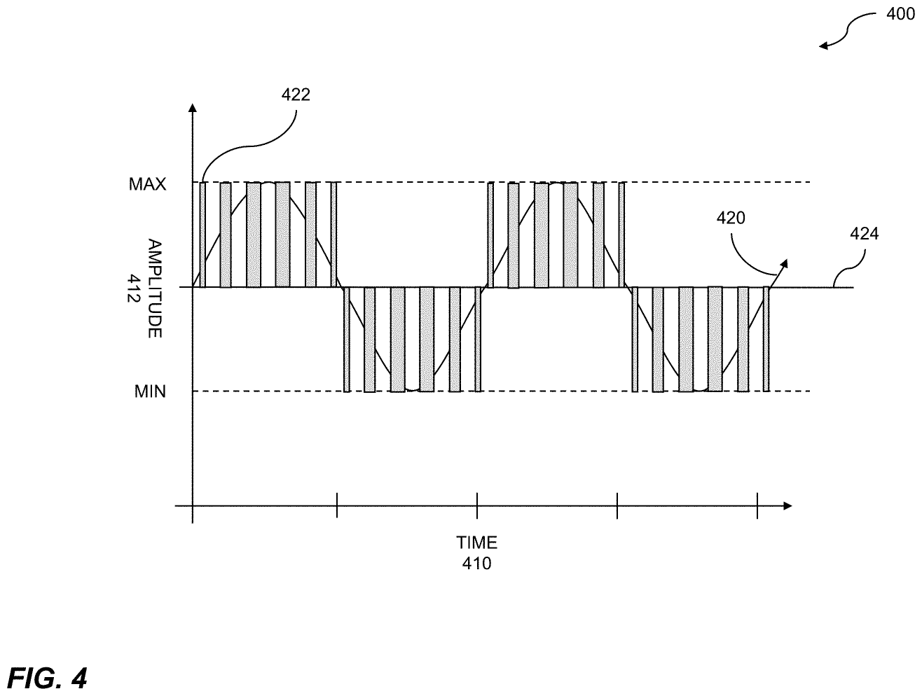

FIG. 4 illustrates pulse width modulation (PWM) of a sinusoid. Waveforms such as sinusoids, ramps, squares, etc., can be synthesized using various techniques. One or more techniques for generating a sinusoid or other waveform can be chosen based on various characteristics of the sinusoid such as frequency, noise tolerance, amplitude, tunability, synchronization with another sinusoid, and so on. By extension, a sinusoidal or AC voltage can be generated from a DC voltage using one or more techniques that can synthesize or reconstruct the AC voltage from the DC voltage. In embodiments, a sinusoid can be generated using pulse width modulation (PWM) 400. Using PWM to synthesize an AC voltage from a DC voltage enables datacenter management using current injection. A datacenter power policy which oversees a datacenter topology is implemented. A supply capacity from a UPS is allocated to loads within the datacenter. An AC current requirement is detected by power control blocks, and AC current is injected into the output network of the UPS.

Pulse width modulation of a sinusoid is shown. PWM can represent a sinusoid or other waveform with pulses of varying durations, frequencies, and duty cycles. The amplitudes of the pulses can be equal. The pulses can be realized by opening and closing a switch between an input and an output. As the sinusoid is represented by a sequence of pulses, the average power delivered to the load or output can be reduced. The amplitude 412 of a sinusoid 420 is plotted versus time 410. A sequence of pulses, such as pulse 422, can be generated. A narrow pulse such as pulse 422 can represent a low current, a medium width pulse can represent an intermediate current, a wide pulse can represent a high current, and so on. Pulses with amplitudes greater than, or more positive with respect to the center line 424, can represent a “positive” portion of the sinusoidal waveform, while pulses with amplitudes less than, or more negative with respect to the center line, can represent a “negative” portion of the sinusoidal waveform. The process can be performed in a constant RMS voltage circuit controlled by the source, and the stored energy voltage can be greater than the peak magnitude of the voltage waveform at the point of the current injection connection. The result is a current flow into the injection point. The PWM as illustrated in FIG. 4 is viewed at the output of the inverter. The connection point is a filtered sinusoidal current and the C-V characteristic of the connection point is not disturbed. A filter component can create a tuned impedance that prevents the source voltage from being affected as the current is injected. The result of the current injection is Power (P), which is defined by the product of the source voltage and the injected current. The load is not affected. The source power is reduced proportionately to the magnitude of the injected current.

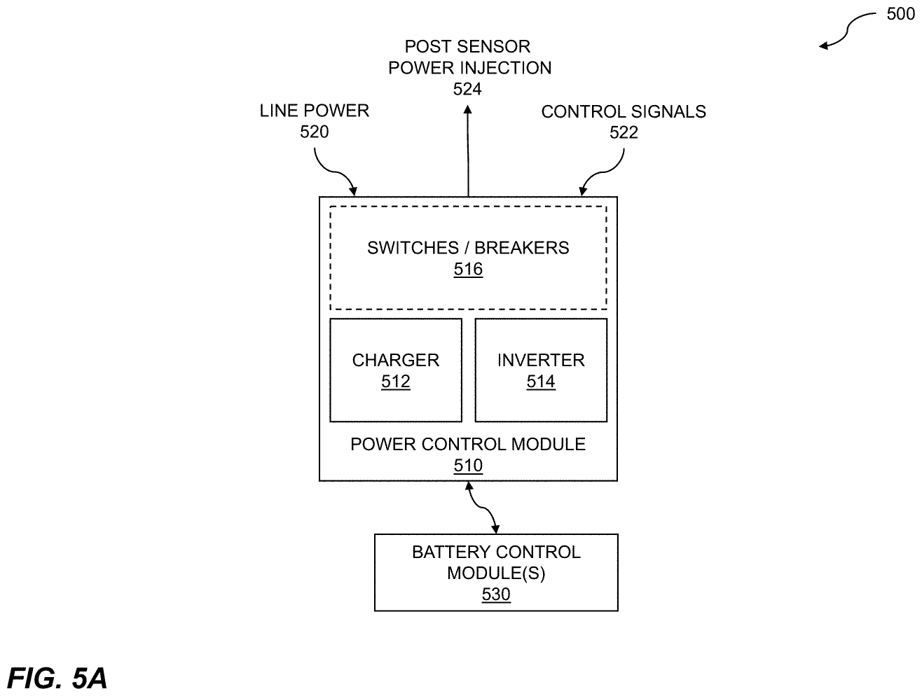

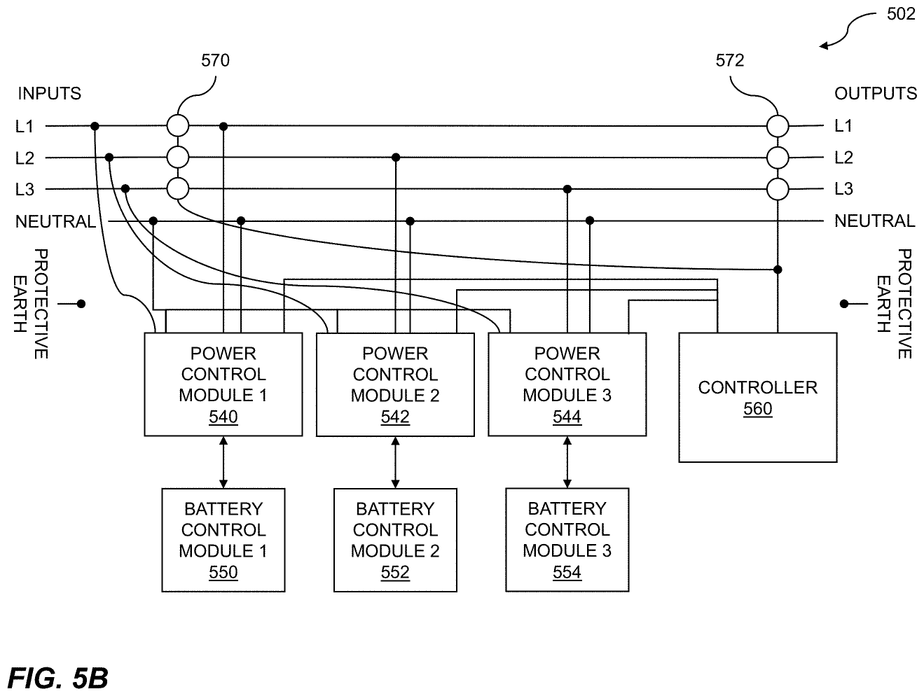

FIG. 5A is a block diagram of a power control module. A power control module 500 can be used to control storage of excess power. The power control module can further be used to inject power into a network such as the output of a UPS, when a detected AC current requirement exceeds the amount of power available at a line input. The power control module enables datacenter power management using current injection. A datacenter power policy is implemented, where the policy oversees a datacenter topology that can include at least one utility grid feed, one or more power caches, one or more power control blocks, one or more loads, and one or more uninterruptible power supplies (UPSs) providing AC power. A supply capacity is allocated from a first UPS to the one or more loads within the datacenter, where the supply capacity is allocated below a peak load requirement for the one or more loads, and where the supply capacity is allocated based on the datacenter power policy. An AC current requirement is detected, by the one or more power control blocks, for the one or more loads at the output network of the first UPS. AC current is injected into the output network of the first UPS, by the one or more power control blocks, based on the detecting and the datacenter power policy.

A power control module 510 is shown. A power control module can be a component within a power control block, where a power control block can include one or more power control modules, one or more battery control modules, and one or more power caches, which can comprise one or more batteries respectively controlled by one or more battery control modules. In embodiments, a one-to-one relationship between battery control modules and power caches (batteries) is not maintained. The power control module can include a charger 512. The charger can convert AC power to DC power, and can use the DC power to charge one or more storage components. The power control module can include an inverter 514. The inverter can be used to convert stored DC power to AC power. In embodiments, the DC power can include a voltage substantially equal the DC voltage, which is greater than the peak AC voltage. This enables current to continually move from the stored energy source to the AC power system when pulse width modulation is used to control the power transfer. In embodiments, the DC power can include a voltage substantially equal to, or greater than, the peak AC voltage being supplied by the inverter. The power control module can be coupled to switches or breakers 516, smart circuit breakers, and the like. The switches or breakers can be located within the power control module, can be located in a power panel coupled to the power control module, and the like. The power control module can receive line power 520. The line power can include single phase power such as 120 VAC. The power control module can be in communication with one or more control signals 522. The control signals can enable or disable switches or breakers, can control the conversion of line power to DC power for charging storage components, and so on. The power control module can inject power 524 into a network such as the output network of a UPS. The power can be injected downstream of one or more current sensors or other sensors. The power control module can be coupled to one or more battery control modules 530. The battery control modules can be used to manage charging one or more batteries, capacitors, or other storage components, which can be integrated within the battery control module. The battery control modules can be used to monitor charge or discharge rate, storage component temperature, storage component health, and so on.

FIG. 5B is a block diagram for power control module usage 502. One or more power control modules can be used convert or to store excess power, where the stored excess power can be used to meet an AC current requirement that can be in excess of available power. Power control module usage enables datacenter power management using current injection. A datacenter power policy is implemented, and a supply capacity from a UPS is allocated. An AC current requirement is detected by one or more power control blocks, and AC current is injected into the output network of a UPS, by the power control blocks, based on the detecting and the datacenter power policy. Power control modules, such as power control module 1 540, power control module 2 542, and power control module 3 544, can be coupled to one or more phases of input power. In the example shown, input three-phase power is shown. The one or more power control modules further can be coupled to neutral and protective earth. The one or more control modules can be coupled to one or more battery control modules such as battery control module 1 550 coupled to power control module 1, battery control module 2 552 coupled to power control module 2, battery control module 3 554 coupled to power control module 3, and so on. Battery control modules are also parallelable in order to create a range of energy storage capacity options for any given power capacity associated with a power control module. A power control module and a battery control module can comprise a power control block.

The one or more power control modules can be controlled by a controller 560. The controller can monitor current at the line inputs using one or more current sensors such as current sensor 570. The controller can control storage of available AC power from the line inputs within batteries or capacitors, conversion of AC power to DC power, DC power conversion to AC power using injection of AC current into an output power system, and so on. The controller can monitor an amount of AC current in an output network using one or more current sensors, such as current sensor 572. Current sensors can be included within physical boundaries of the unit represented by block diagram 502, or they can be moved external to the physical boundaries to support primary and auxiliary unit functionality. In embodiments, the AC current that can be injected by the one or more power control blocks can be sourced by at least one of the one or more power caches. A power cache can include one or more batteries, one or more capacitors, and so on. The power control blocks can be managed or controlled by the datacenter power policy, where the datacenter power policy can be issued to individual hardware components within a datacenter topology. The power control module block diagram 502 can describe elements of an energy block for use in datacenter power management.

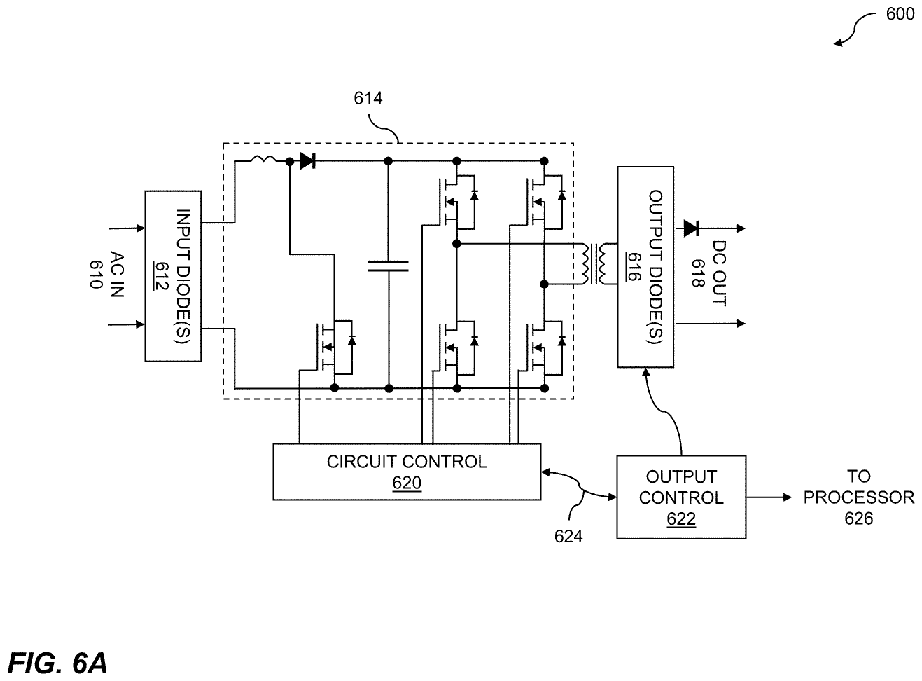

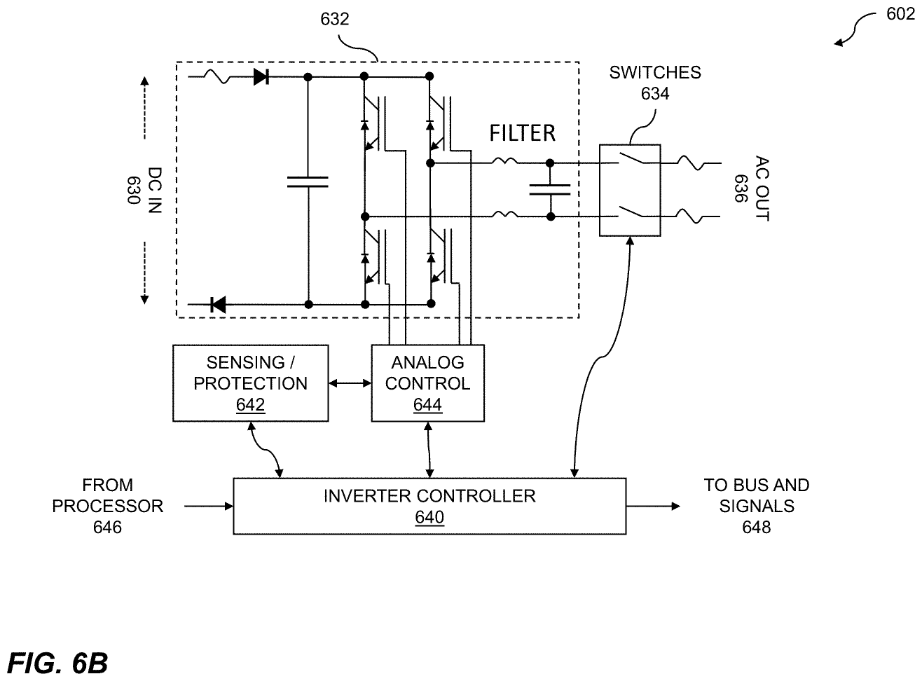

FIG. 6A is a block diagram for a charger. A power control block can store energy when excess energy is available, and source energy when energy is required to meet a detected AC current requirement. Excess energy can be available for use when the amount of energy available exceeds the amount of energy required to meet load demand at a given time (dI/dt). The excess energy harvesting technique enables capture of the excess energy for later use. The energy that is captured by energy harvesting can include excess AC current. In order the store the excess AC current, the excess AC power can be converted to DC power, where the DC power can be stored as energy in a DC storage cache. The DC energy can be stored in batteries, capacitors, and so on. The capturing and storing of the excess AC energy support datacenter power management using current injection. A datacenter power policy is implemented, and a supply capacity from a UPS is allocated. An AC current requirement is detected, and AC current is injected into the output network of the UPS.

Energy can be stored in batteries, capacitors, and so on, by charging the batteries or capacitors. A block diagram for a charger is shown 600. An AC input, such as a 120 VAC signal, can be provided at an input 610 to the charger. The input signal can be rectified using input diodes 612. The rectified signal can be applied to a charger circuit 614. The charger circuit can be controlled by circuit control 620. The circuit control can be used to monitor current, voltage, temperature, and so on for the charger circuit; to monitor current or voltage being provided to storage batteries or capacitors; to monitor charge state or temperature of the batteries or capacitors; and the like. The voltage or current generated by the charger circuit can be coupled to output diodes 616 through a transformer. The output from the output diodes, DC output 618, can be used to charge storage batteries, storage capacitors, etc. The output of the charger can be controlled by output control 622. The output control, which can be coupled 624 to the circuit control, can be used to control charging of one or more types of batteries, capacitors, etc. In a usage example, the output control can provide constant current during initial charging, then can provide constant voltage after a charge level threshold has been attained. The output control can be used to monitor the battery, thereby preventing damage to or catastrophic failure of the battery. Such battery management can also provide a safer use environment for the battery and/or an extended battery lifetime, among other benefits. The circuit control and the output control can be coupled to a processor 626. The processor can include a PC, a microprocessor, a microcontroller, and so on.

FIG. 6B is a block diagram for a single-phase inverter. Power can be injected by one or more power control blocks into a network such as the output network of a UPS. Discussed throughout, the power control blocks, the power caches, or the battery control modules can store energy collected when power capacity is greater than load demand and can provide energy based on a detected AC current requirement. One or more single-phase inverters can support datacenter power management using current injection. A single-phase inverter block diagram is shown 602, where the single-phase inverter can be used to generate an AC output based on stored energy. The stored energy, which can be stored in batteries, capacitors, and so on, can be used to provide a DC input 630 to an inverter circuit 632. The inverter circuit can be coupled to switches 634, breakers, smart breakers, and so on, where the switches can be used to couple the output of the inverter to an AC output 636. The AC output voltage 636 is set by the constant voltage, constant frequency output of the UPS system, or another power source. The DC input voltage is greater than the peak magnitude of AC source voltage. The inverter control techniques and the output filter convert the inverter output to an AC current in phase with and with the same frequency as the source voltage, using pulse width modulation techniques. The resulting current injection transfers power to the power system at the connection point without disturbing the constant voltage, constant frequency characteristics. The inverter can be controlled by an inverter controller 640. The inverter controller can perform sensing and protection 642 such as over or under voltage of the DC input, presence of a DC input voltage, over current of the AC output, and the like. The inverter controller can operate analog control 644 of the inverter. The inverter controller can communicate with a processor 646. The processor, which can include a PC, a microprocessor, etc., can be used to apply a datacenter power policy. The inverter can be coupled to a bus or to signals 648, where the bus can include a bus within a data rack, between data racks, etc. The signals can include control signals, operating values, and the like. In embodiments, three single-phase inverters such as 602 can be applied to injection of AC current into three-phase AC power. A filter is shown before switches 634 and output 636, which includes series inductors and a capacitor between the output lines. This filter can be used in conjunction with the PWM applied to the DC voltage, as described in the FIG. 4 section. The output impedance of circuit 632 allows a source voltage to exist on the output side of the circuit while current is flowing through the output. This output point is held at a constant voltage by the source, and the injected current is in phase with the voltage. This results in less current being required by the source to supply the load, and hence less power demand.

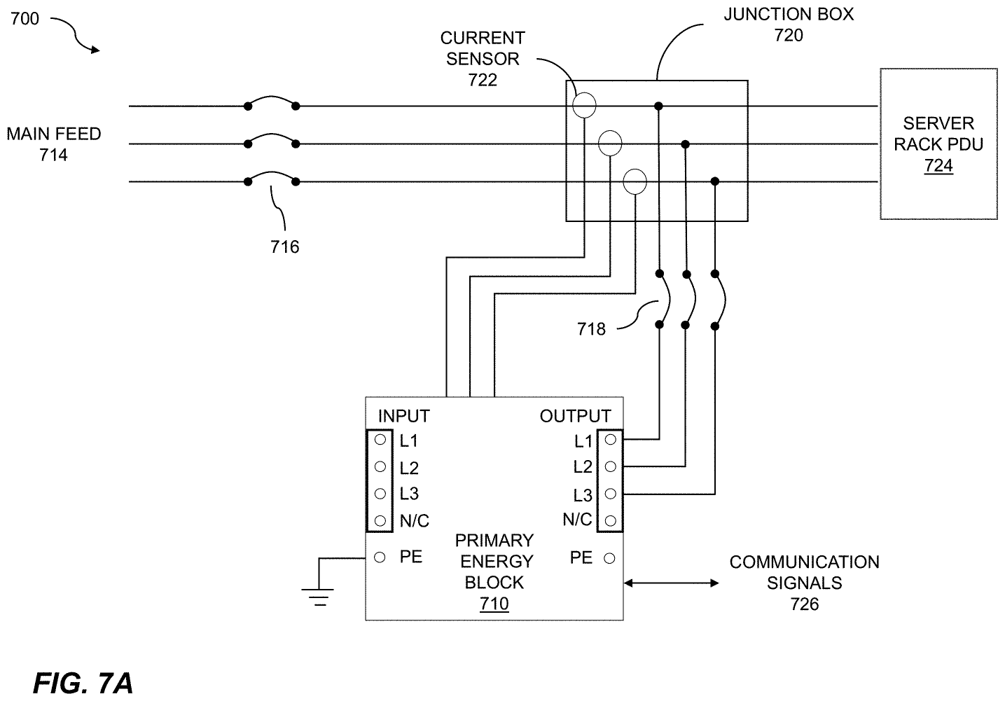

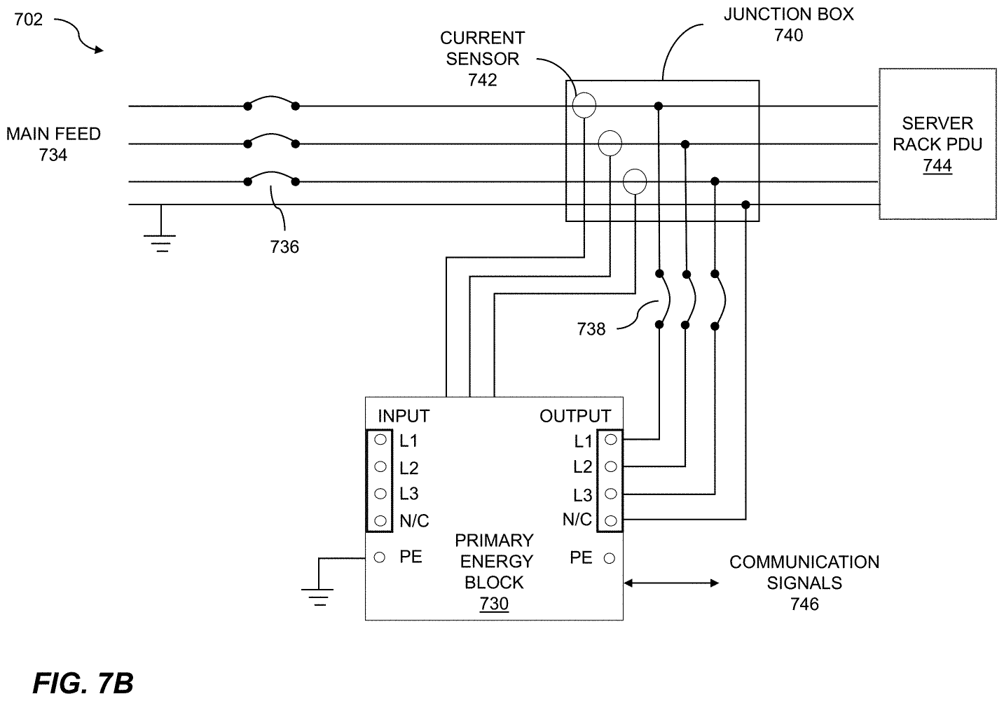

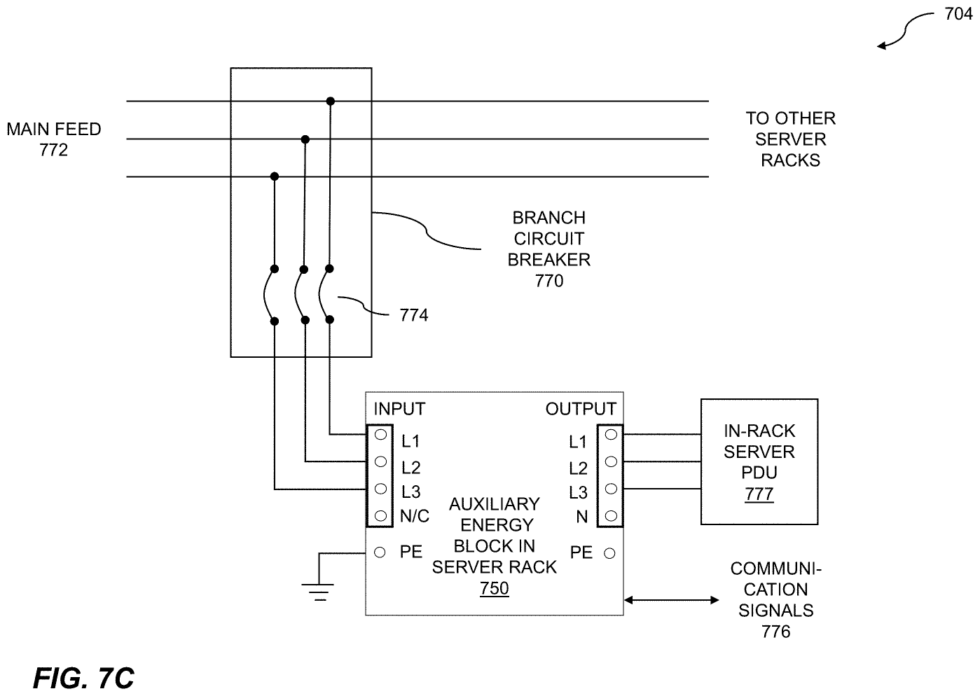

FIG. 7A shows parallelable energy control with three wire and protective earth. Discussed throughout, power control and management can be used for power conditioning, energy storage, power delivery, peak shaving, and other power-related tasks within a datacenter. The various power control and management techniques can be applied to computing equipment, electrical equipment, etc., located within the datacenter. Datacenter power management uses current injection. A datacenter power policy is implemented, where the policy oversees a datacenter topology that can include at least one utility grid feed, one or more power caches, one or more power control blocks, one or more loads, and one or more uninterruptible power supplies (UPSs) providing AC power. A supply capacity is allocated from a first UPS to the one or more loads within the datacenter, where the supply capacity is allocated below a peak load requirement for the one or more loads, and where the supply capacity is allocated based on the datacenter power policy. An AC current requirement is detected, by the one or more power control blocks, for the one or more loads at the output network of the first UPS. AC current is injected into the output network of the first UPS, by the one or more power control blocks, based on the detecting and the datacenter power policy.

Power conditioning and energy storage can be accomplished using a variety of techniques. In disclosed techniques, parallelable energy control is shown 700. Energy blocks, which can be used for power management, can be connected to one or more power distribution units (PDUs), which supply one or more racks within a datacenter. Energy blocks can comprise configurations of one or more power control blocks. Power management can be accomplished using one or more components, where one or more components can be configured using a parallel technique. Power management can include one or more energy blocks such as primary energy block 710, and so on. Embodiments may include dual primary energy blocks for N+1 control and feedback. In other embodiments, systems are used in pairs for a 2N power system in order to maintain the same, or improve, the availability. An energy block can be used to store energy, to inject current into an output network of a UPS, and so on. While two energy blocks are shown, other numbers of energy blocks can be used. An energy block can be used to control energy allocation from multiple sources, where the multiple sources can include grid power, alternative energy power, backup power, batteries, capacitors such as supercapacitors, and the like. The one or more energy blocks can allocate energy from the various sources based on a datacenter power policy. The one or more energy blocks can be located within a single data rack, distributed among data racks within a datacenter, etc.

The one or more energy blocks such as energy block 710 and other energy blocks (not shown) can be coupled to a power panel, or junction box, 720. The power panel can include switches, circuit breakers, smart circuit breakers, etc. In the example shown, circuit breakers 716 that can cut off main feed 714 power to the panel can be included. Additional circuit breakers 718 can enable power distribution from the one or more energy blocks. The connections between the one or more energy blocks and a power panel can be bidirectional. The power panel or junction box 720, which can include a main power panel for the datacenter, can include one or more current sensors such as current sensor 722. A current sensor can be associated with a power phase, such as a phase of single-phase power, a phase of three-phase power, and so on. The one or more switches or breakers 718 can be used to connect the one or more power control blocks, such as the primary energy block 710 and an auxiliary energy block (not shown), to the one or more phases of the line power, in parallel. The power panel 720 can supply power to server rack power distribution unit (PDU) 724. Energy block 710 can be controlled by and can communicate with a datacenter power management system using communication signals 726.

FIG. 7B shows parallelable energy control with three wire, neutral, and protective earth for wye configuration 702. One or more energy blocks can be used to store and provide AC current to meet a detected AC current load requirement within a datacenter. Parallelable energy control with three wire, neutral, and protective earth can enable datacenter power management using current injection. The use of three-phase power is common within a datacenter. Three-phase power configurations provide power to the datacenter using three “hot” leads and a neutral lead. The voltages on the three hot leads are separated from each other by 120 degrees. That is, phase 1 is separated from phase 2 by 120 degrees, phase 2 is separated from phase three by 120 degrees, phase 3 is separated from phase 1 by 120 degrees. Three-phase power provides 208 VAC between any two hot leads, and 120 VAC between any hot lead and neutral. The energy control with three wire, neutral, and protective earth can be configured in a delta configuration, a wye configuration, etc. The delta configuration or the wye configuration can be used to balance the power loads among the three power phases. In a wye configuration, the neutral lead is coupled to the center of a “Y” shaped circuit, where the ends of three arms of the “Y” are each coupled to a power phase. The wye configuration supports provision of both 120 VAC and 208 VAC power. Of course, other typical three-phase voltage scenarios exist, such as 480 VAC lead-to-lead and 277 VAC lead-to-neutral.

Power management based on three wire, neutral, and protective earth for wye configuration can include one or more energy blocks such as primary energy block 730 and one or more auxiliary energy blocks (not shown) connected in parallel. Energy block 730 can be coupled to a power panel, or junction box, 740. The power panel can include switches, circuit breakers, smart circuit breakers, etc., which can be included within or without the power panel in order to cut off power to the panel. For example, circuit breakers 736 can cut off each phase of main feed 734 from power panel 740. Additional circuit breakers 738 can enable power from the one or more energy blocks 730 to power panel 740. The connections between the one or more energy blocks and a power panel can be bidirectional, where the connections can be used to store power within a power control block or to source energy from a power control block. The power panel can couple power such as three-phase power between line power sources and power loads. The power panel can include a lead for each phase and a neutral lead. The power panel can include one or more current sensors such as current sensor 742. A current sensor can be associated with a power phase, such as a phase of single-phase power, a phase of three-phase power, and so on. The power panel 740 can supply power to server rack power distribution unit (PDU) 744. Energy block 730 can be controlled by and can communicate with a datacenter power management system using communication signals 746.

FIG. 7C shows serial energy control with three wire and protective earth. While parallelable energy control has been described previously, energy block series connections can connect the source power for a rack to the rack power distribution equipment. An example of connecting an energy block in series 704 is shown. It can include an energy block 750 being supplied by main feed 772 through branch circuit breaker 770. The branch circuit breaker 770 can include individual wire, or phase, circuit breakers 774, which supply input current from the main feed 772 to energy block 750. Energy block 750 can be an auxiliary energy block in a server rack. Energy block 750 can supply power to an in-rack load or server PDU 777 in the manner described herein. Energy block 750 can be controlled by and can communicate with a datacenter power management system using communication signals 776. The connecting of the energy blocks in series can eliminate the need to provide additional power connections between the data rack and a power panel. Various power control block configurations to support other datacenter requirements, such as single phase systems, are possible, including serial energy control with three wire, neutral, and protective earth.

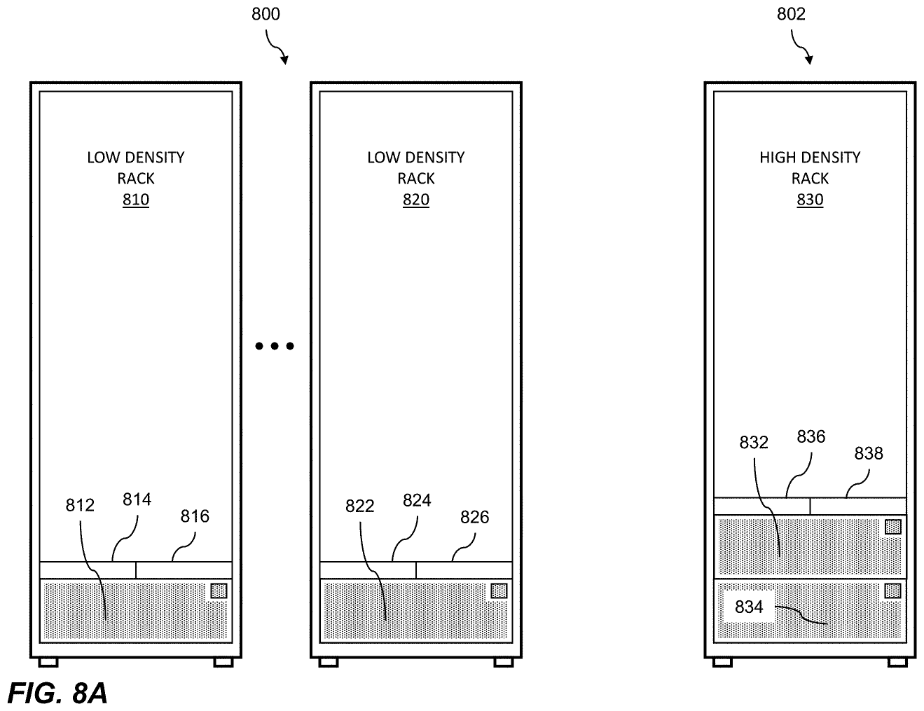

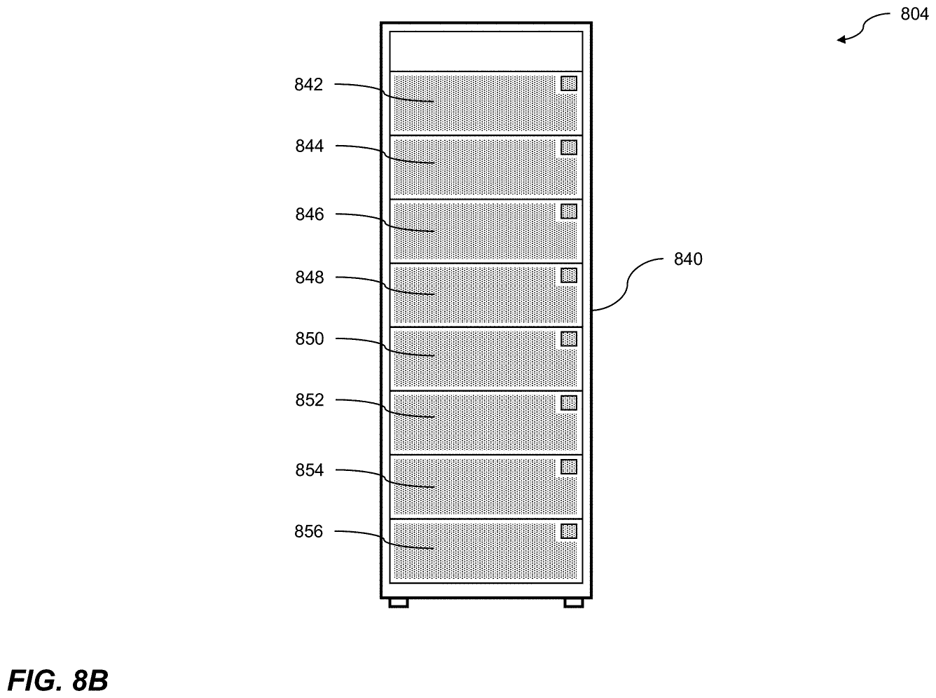

FIG. 8A illustrates example rack density configurations. Data racks or information technology (IT) racks can contain computing equipment, communication equipment, and other electrical equipment. The electrical equipment can include power supplies, power caches such as batteries or supercapacitors, uninterruptable power supplies, and so on. Power to the electrical equipment within the data racks can be managed, where the power management can include datacenter power management using current injection. A datacenter power policy is implemented, where the policy oversees a datacenter topology that includes at least one utility grid feed, one or more power caches, one or more energy control blocks, one or more loads, and one or more uninterruptible power supplies (UPSs) providing AC power. A supply capacity is allocated from a first UPS to the one or more loads within the datacenter, where the supply capacity is allocated below a peak load requirement for the one or more loads, and where the supply capacity is allocated based on the datacenter power policy. An AC current requirement is detected, by the one or more energy control blocks, for the one or more loads at the output network of the first UPS. AC current is injected into the output network of the first UPS, by the one or more energy control blocks, based on the detecting and the datacenter power policy.

The figure illustrates two example density configurations, a low-density configuration 800, and a high-density configuration 802. One or more batteries, one or more power supplies, a plurality of connectors, a plurality of power sensors, a plurality of load sensors, and controllers can comprise a consolidated rack mount power system. An example system is shown in the low-density configuration 800 which includes racks 810 and 820. In embodiments, a low-density configuration can accommodate a rack with a power density comprising about 9 kVA, which is half of the total available power density of about 18 kVA. The racks can in turn be composed of a consolidated rack mount power system and energy storage units such as 812 and 822, and power switches which can be included within the consolidated rack mount power systems. The racks can further include power control systems such as 814 and 816 within rack 810, and 824 and 826 within rack 820. While two low-density racks 810 and 820 are shown, further low-density racks can be added. The added racks can be configured similarly to racks 810 and 820, can be configured as capacity expansion racks, and so on. In embodiments, the power capacity of a capacity expansion rack can comprise about 18 kVA. A capacity expansion rack can comprise a consolidated rack mount power system, a power switch, two PDUs, and so on.

A further example system is shown in the high-density configuration 802 such as rack 830. In embodiments, a high-density configuration can accommodate a rack with a power density comprising up to 18 kVA. The rack 830 can in turn be composed of dual consolidated rack mount power system and energy storage units such as stacked rack mount power systems 832 and 834, and power switches within the consolidated rack mount power systems. The rack can further include power control systems such as 836 and 838. While one high density rack is shown, further high-density racks can be added, where the added racks can be configured similarly to rack 830. The stacking can provide for N+ parallelization. N+ parallelization refers to a number of additional power supplies beyond the required number which are kept as standby or reserve power supplies. For example, if a particular cluster of racks requires six power supplies, an N+1 configuration would provide seven power supplies, an N+2 configuration would provide eight power supplies, and so on. The stacking can also provide for 2N parallelization. Returning again to the example of six required power supplies, a 2N parallelization scheme would provide twelve power supplies. In the 2N redundancy configuration, any critical path in the power system is replicated to remove single points of failure and to increase robustness. The consolidated power system can also provide power across multiple racks. For example, a single consolidated power system can provide power across a first rack and a second rack, where the first rack and the second rack can be adjacent racks, remote racks, and so on.

FIG. 8B illustrates a parallel stack configuration. The parallel stack configuration 804 can sense total feed current for a plurality of datacenter racks or IT racks within a datacenter. In embodiments, the plurality of datacenter racks comprises a datacenter row such as a row of servers or other electrical equipment associated with IT. The parallel stack configuration can enable datacenter power management using current injection. Similar to the low density and high density rack configurations, the one or more batteries, the plurality of power supplies, the plurality of connectors, the plurality of power sensors, the plurality of load sensors, the plurality of converters, and the controllers associated with the parallel stack configuration can comprise a consolidated rack mount power system. An example setup is shown in configuration 804 which includes rack 840. The example setup further includes a plurality of consolidated rack mount power systems such as consolidated rack mount power and energy storage systems 842, 844, 846, 848, 850, 852, 854, and 856. While eight consolidated rack mount power systems are shown, other numbers of power systems can be included within a single datacenter rack, adjacent racks, racks distributed throughout a datacenter, and so on. A rack in parallel stack configuration can further include two or more PDUs (not shown). A consolidated power system within the plurality of consolidated power systems can be operated as a primary source or an auxiliary source. A primary source can receive source current information. Two or more consolidated power systems can be configured as primary sources to accomplish redundancy. The primary sources can perform peak shaving while providing current to various power loads.

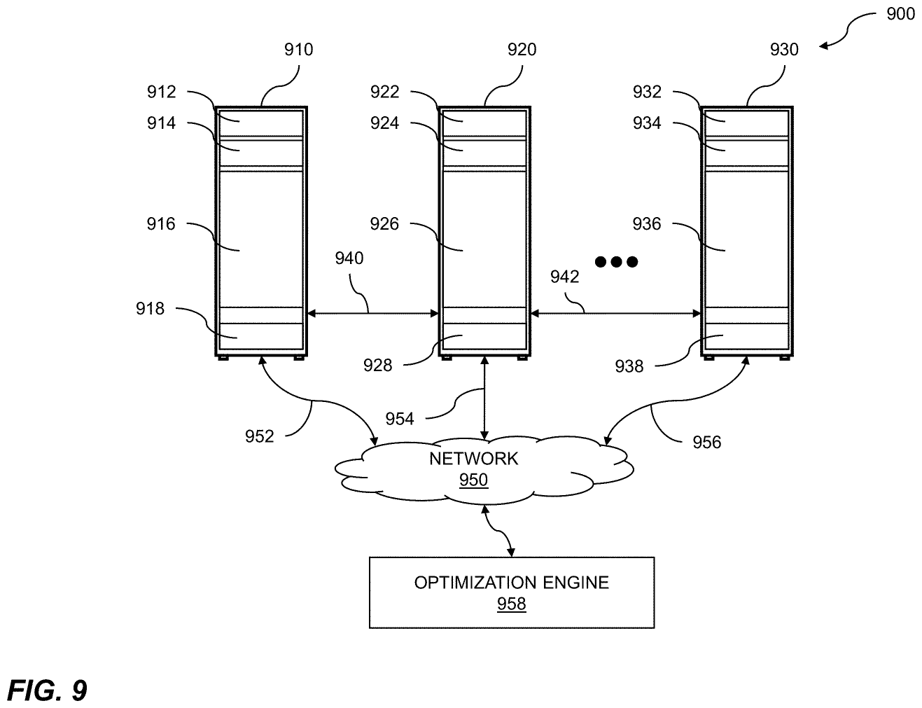

FIG. 9 shows a datacenter rack configuration. Data racks, also called information technology (IT) racks, contain a variety of electrical equipment components for which power is controlled. A datacenter can include multiple data racks to which power management is provided. Power management includes datacenter power management using current injection. A datacenter power policy is implemented, and a supply capacity from a first UPS is allocated to one or more loads within the datacenter. The policy oversees a datacenter topology that may include at least one utility grid feed, one or more power caches, one or more power control blocks, one or more loads, and one or more uninterruptible power supplies (UPSs) providing AC power. An AC current requirement is detected, by the power control blocks, for the output network of the first UPS. AC current is injected into the output network of the first UPS, by the power control blocks, based on the detecting and the datacenter power policy.

A datacenter can include multiple data or IT racks. Example 900 includes three data racks, indicated as rack 910, rack 920, and rack 930. While three data racks are shown in example 900, in practice, there can be more or fewer data racks. The data rack 910 includes a power cache 912, a first server 914, a second server 916, and a power supply 918. The power supply 918 can be used for AC-DC conversion and/or filtering of power to be used by the servers 914 and 916, as well as replenishment of the power cache 912. In embodiments, the power cache 912 includes an array of rechargeable batteries. In embodiments, the batteries include, but are not limited to, lead-acid, nickel metal hydride, lithium ion, nickel cadmium, and/or lithium ion polymer batteries. Similarly, the data rack 920 includes a power cache 922, a first server 924, a second server 926, and a power supply 928. Furthermore, the data rack 930 includes a power cache 932, a first server 934, a second server 936, and a power supply 938. The data racks are interconnected by communication links 940 and 942. The communication links can be part of a local area network (LAN). In embodiments, the communication links include a wired Ethernet, Gigabit Ethernet, or another suitable communication link. The communication links enable each data rack to send and/or broadcast current power usage, operating conditions, and/or estimated power requirements to other data racks and/or upstream controllers such as a cluster controller. Thus, in the example 900, a power cache can be located on each of the multiple data racks within the datacenter. In embodiments, the power cache includes multiple batteries distributed across the multiple data racks.

Each rack may be connected to a communication network 950. Rack 910 is connected to network 950 via communication link 952. Rack 920 is connected to network 950 via communication link 954. Rack 930 is connected to network 950 via communication link 956. The optimization engine 958 can retrieve operating parameters from each rack. In embodiments, the operating parameters are retrieved via SNMP (Simple Network Management Protocol), TR069, or some other suitable protocol for reading information. Within a Management Information Base (MIB), various Object Identifiers (Ms) may be defined for parameters such as instantaneous power consumption, average power consumption, number of cores in use, number of applications currently executing on a server, the mode of each application (suspended, running, etc.), internal temperature of each server and/or hard disk, and fan speed. Other parameters may also be represented within the MIB. Using the information from the MIB, the optimization engine 958 may derive a new dispatch strategy in order to achieve a power management goal. Thus, embodiments include performing the optimizing with an optimization engine.

Other power system deployments supported by energy blocks can include power shelves used in alternate open source rack standards, small footprint parallel connected blocks in dedicated racks housing switch gear, and even applications beyond data centers—wherever mission critical power systems have unused redundant capacity, and so on.

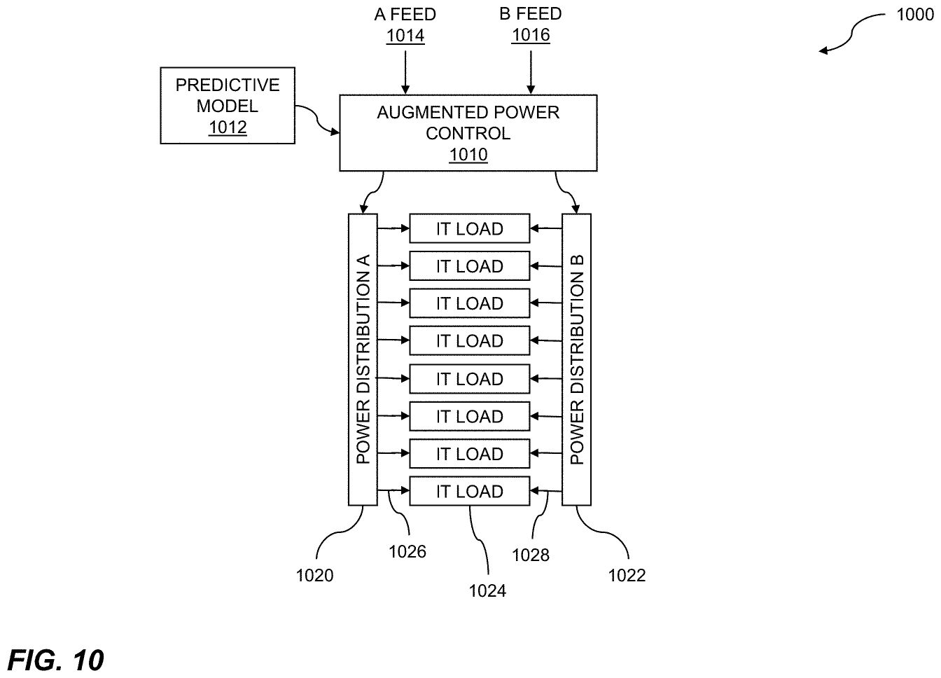

FIG. 10 illustrates augmented power control using predictive modeling. The datacenter can include a plurality of data racks, also called information technology (IT) racks, in which a plurality of IT equipment and other electrical equipment can be placed. The IT equipment can include devices such as servers, blade servers, communications switches, backup data storage units, communications hardware, and other devices. The electrical equipment can include one or more of processors; data servers; server racks; heating, ventilating, air conditioning (HVAC) units; uninterruptable power supplies (UPSs); power caches; backup power; and so on. The power that is provided to the IT equipment and other electrical equipment can be managed, where the management of the power can be based on the availability of power, power policies for the datacenter, contractual agreements, and so on. Datacenter power management can be accomplished using current injection. Further management of the IT equipment and electrical equipment can be augmented based on predictive models for power usage.

An example configuration for power control is shown 1000. Augmented power control 1010 can be used to control the configuration of a datacenter power structure. Configuration of the datacenter power structure includes distributing power such as grid power, locally generated power, and so on, to information technology (IT) loads. The IT loads can be located in data racks and IT racks throughout the datacenter. The augmented power control can be based on a predictive model 1012. The predictive model can include a power prediction model, where the power prediction model can include predicted power usage and a power correlation model. The power prediction model can be used to predict power usage requirements by the IT and electrical equipment at a time subsequent to the time at which the prediction model was calculated. The power prediction model can be updated, changed, replaced, refined, and so on, by correlating predicted power usage with measured power usage. Power including an A feed 1014 and a B feed 1016 can be controlled by augmented power control 1010. The power from the A feed and from the B feed can include grid power, locally generated power, battery power, backup power, and so on.

The power from the augmented power control can be distributed to IT equipment throughout a datacenter. The IT equipment includes IT loads 1024. The power, augmented power, backup power, and so on, can be distributed to the IT equipment through a power distribution unit (PDU) or using another power distribution technique. Two power distribution units are shown, power distribution A 1020 and power distribution B 1022. The power distribution units A and B can selectively distribute power to the IT equipment. Whether power is distributed from a feed to an IT load can be selectively controlled by the augmented power control. Power is distributed to the IT loads via a plurality of power connections. Power is distributed to the IT loads from feed A via power connections 1026, and power is distributed to the IT loads from feed B via power connections 1028. The IT loads can be powered by power distribution A, power distribution B, or both power distribution A and power distribution B.

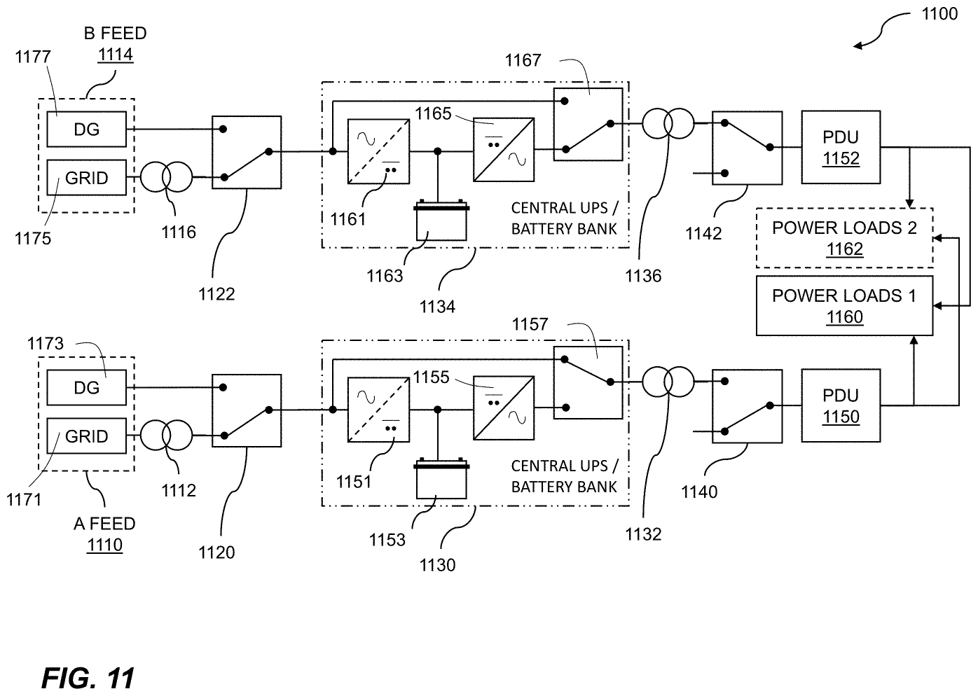

FIG. 11 shows a topology representation with multiple sets. Power, space, cooling, and other critical resources of a datacenter can be based on a policy, where the policy can include power management. The power management can include datacenter power management using current injection. A datacenter power policy is implemented, where the policy oversees a datacenter topology that includes at least one utility grid feed, power caches, power control blocks, loads, and uninterruptible power supplies (UPSs) providing AC power. A supply capacity from a first UPS is allocated to the loads within the datacenter. The supply capacity is allocated below a peak load requirement for the loads, and where the supply capacity is allocated based on the datacenter power policy. An AC current requirement is detected, by the power control blocks, for the loads at the output network of the first UPS. AC current is injected into the output network of the first UPS, by the power control blocks, based on the detecting and the datacenter power policy.

The topology representation 1100 includes a first main power source 1110, referred to as the “A feed.” The topology representation 1100 further includes a second main power source 1114, referred to as the “B feed.” Each feed is capable of powering each device in the datacenter independently. This configuration is referred to as 2N redundancy for power. The A feed 1110 includes a grid source 1171, and a secondary, local source of a diesel generator (DG) 1173. The grid source 1171 is input to a power regulator 1112 and then goes into one input of a switch block 1120. The diesel generator 1173 is connected to a second input of the switch block 1120. The switch block 1120 can be configured, by arrangement of a power policy, to select the diesel generator source or the grid source. The switch block 1120 feeds into an uninterruptable power supply (UPS) 1130. The UPS 1130 includes an AC-DC converter 1151 configured to charge a power cache 1153. In embodiments, the power cache 1153 is a battery. The UPS 1130 further includes a DC-AC converter 1155 that feeds into an input of a switch block 1157. The output of the switch block 1120 feeds into a second input of the switch block 1157. The output of the UPS 1130 is input to a power regulator 1132, and then goes to an input of a switch block 1140. The switch block 1157 can be configured, based on a power policy, to provide power from the power cache, or to bypass the power cache and provide power directly from the local or grid power source. The second input of the switch block 1140 is not connected, such that if the second input is selected, the A feed 1110 is disconnected from the PDU 1150. The PDU (Power Distribution Unit) distributes power within a datacenter and feeds the power loads 1160 within the datacenter. In embodiments, a second set of power loads 1162 may be added as part of a simulation of a dynamic power scenario. A controller (not shown) can control the PDU 1150. The controller can be an intelligent power controller. The controller can receive a power policy for use in the datacenter. The controller can use a key. The key can be used to support secure communications to and from the controller. The key from controller can be uploaded by a user, downloaded from the Internet, embedded in the controller, and so on. The PDUs 1152 and 1150 can have the ability to shut off their branch circuits. This type of power control goes with current injection in terms of holding up a load using current injection until the software can migrate the IT work load elsewhere, and then it is completely shed by disconnecting the rack from the power system. This allows the process of dynamically using redundant power capacity which becomes possible when current injection capability is available. Dynamic redundant capacity can be used up to a limit in the upstream power system. In most cases, significant power is available to create IT workloads with a lower availability SLA, as could be the case with power load rack 1160, which can have a means to disconnect under software control.

Similarly, the B feed 1114 includes a grid source 1175, and a secondary, local source of a diesel generator (DG) 1177. The grid source 1175 is input to a power regulator 1116 and then goes into one input of a switch block 1122. The diesel generator 1177 is input to a second input of the switch block 1122. The switch block 1122 can be configured, based on a power policy, to select the diesel generator source or the grid source. The switch block 1122 feeds into a UPS 1134. The UPS 1134 includes an AC-DC converter 1161 configured to a charge power cache 1163. In embodiments, the power cache 1163 may be a battery. The UPS 1134 further includes a DC-AC converter 1165 that feeds into an input of a switch block 1167. The output of the switch block 1122 feeds into a second input of a switch block 1167. The switch block 1167 can be configured, based on a power policy, to provide power from the power cache, or to bypass the power cache and provide power directly from the local or grid power source. The output of the UPS 1134 is input to a power regulator 1136, and then goes into an input of a switch block 1142. The second input of the switch block 1142 is not connected, such that if the second input is selected, the B feed 1114 is disconnected from the PDU 1152, which in turn feeds the first set of power loads 1160 and/or the second set of power loads 1162 within the datacenter. A controller (not shown) can control the PDU 1152. The controller can receive a power policy for use in the datacenter. The controller can use a key. The key can be used to support secure communications to and from the controller. The key can be uploaded by a user, downloaded from the internet, embedded in the controller, and so on.

Thus, the A feed 1110 and the B feed 1114 comprise a first main power source and a second main power source. The first power source and the second power source can provide 2N redundancy to the power load. Furthermore, in embodiments, the power source and a second power source share power to the multiple data racks, wherein the power is shared on a fractional basis. Power loads 2 1162 can be configured to utilize the redundant capacity of a 2N power system. Without the ability to inject current, it is not possible to use the redundant capacity. However, it is possible to create more than 50% load on each feed of a 2N system to the extent that there is upstream capacity available. This could involve rating a single utility feed for a greater power capacity than the combined redundant pathways typically called the A and B feed. Or, this could involve two fully rated utility feeds which are able to supply the full load of the A or B systems. In order to utilize this redundant capacity, it is necessary to hold up the extra load in the event that one of the power feeds in a 2N system is no longer available, until such time as the software can migrate the workloads elsewhere and/or shut off the racks. Once the load has been shed, the current injection stops. The remaining UPS could be at full capacity after the event sequence is completed, and the overloaded period will have been avoided by using current injection. This can significantly increase the capacity of a datacenter beyond what would be possible without datacenter management using current injection. This process can be defined as an outcome that is available once current injection downstream of a UPS is enabled. In embodiments, the injecting enables using redundant power from two utility feeds in a 2N system to double power available to the datacenter topology.

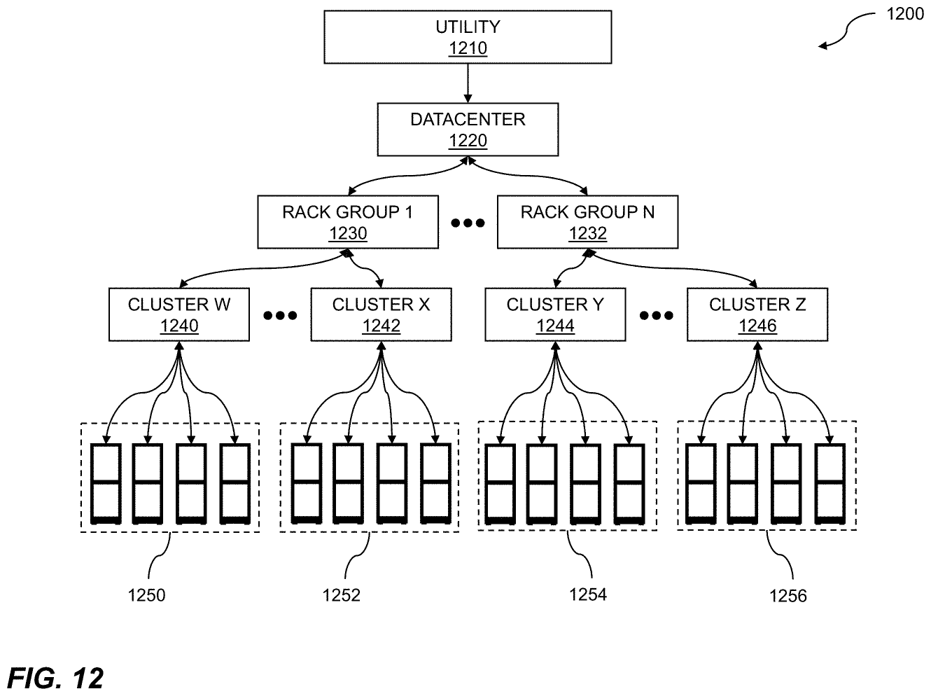

FIG. 12 illustrates hierarchical allocation of power control. Power management can be accomplished based on datacenter power management using current injection. The current injection does not perturb a voltage supplied by an upstream source. The current injection does not perturb a phase of AC frequency supplied by an upstream source. The injecting can be controlled using pulse width modulation. A datacenter power policy is implemented, and a supply capacity is allocated from a first UPS, based on the power policy. An AC current requirement is detected, by power control blocks, for loads at the output network of the first UPS. AC current is injected into the output network of the first UPS by the power control blocks. The example 1200 includes a utility 1210 as the top level of the hierarchy. The utility can include a local or regional energy provider. The example 1200 further includes a datacenter 1220 that receives power from the utility 1210. Within the datacenter 1220, the next downstream level of the hierarchy is the group level. The group level includes multiple groups, indicated as rack group 1 1230 and rack group N 1232. Each group can have a group policy. The group policy can include a hierarchical set of policies. Within the groups, the next downstream level of the hierarchy is the cluster level. The rack group 1230 includes multiple clusters, indicated as clusters W 1240 and X 1242. The group 1232 includes multiple clusters, indicated as clusters Y 1244 and Z 1246. Thus, in embodiments, the datacenter comprises a plurality of clusters of data racks. Each cluster includes multiple data racks. The cluster 1240 includes the data racks 1250. The cluster 1242 includes the data racks 1252. The cluster 1244 includes the data racks 1254. The cluster 1246 includes the data racks 1256. Thus, the datacenter can include a plurality of clusters of data racks. In embodiments, the power cache comprises multiple batteries spread across the multiple data racks. Embodiments include dynamically allocating power from the power source across the plurality of data racks.

In some embodiments, a dual utility feed for a 2N system is implemented, where the two utility feed sources are not joined until they reach the actual two-corded IT power equipment using redundant power supplies. Both sources can then operate at 100% of the design capacity during normal operations, instead of operating at only 50% capacity, which would be required if current injection were not available. In the event one feed is lost, then current injection is used to hold up the load so the remaining system is not overloaded until the software sheds the excess load based on having racks with lower availability requirements, which may be allowed and defined in a datacenter SLAs for that load.

During operation of the system, power policies are propagated downstream from the datacenter 1220 to the group level, and from the group level to the cluster level, and from the cluster level to the data rack level. The datacenter comprises multiple data racks. Operating conditions and/or power requirements are sent upstream. Thus, each data rack reports operating information to a cluster controller within its corresponding cluster. Each cluster reports operating information to a group controller within its corresponding group. Each group reports operating information to a datacenter controller. In this way, information, status, and operating conditions can quickly propagate through the system to allow power policies to act on the reported information in a timely manner. The datacenter configuration is based on the refined power usage prediction. Learning is performed to determine the power correlation model.

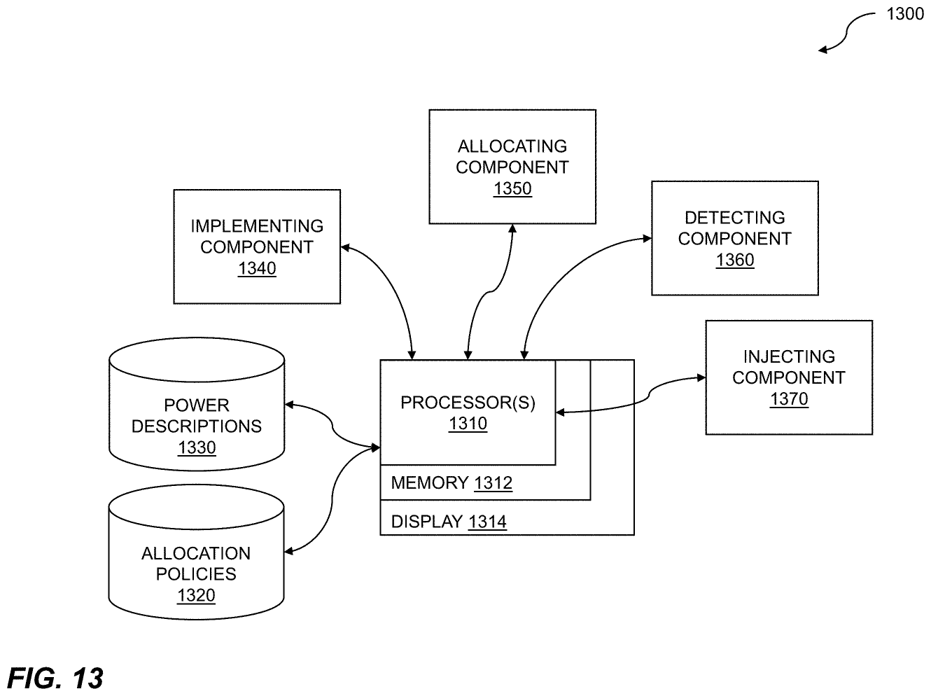

FIG. 13 is a system diagram for datacenter power management using current injection. A datacenter power policy is implemented, where the policy oversees a datacenter topology. The datacenter topology includes at least one utility grid feed, one or more power caches, one or more power control blocks, one or more loads, and one or more uninterruptible power supplies (UPSs) providing AC power. A supply capacity is allocated from a first UPS to the loads within the datacenter. The supply capacity is allocated below a peak load requirement for the loads, and the supply capacity is allocated based on the datacenter power policy. An AC current requirement is detected, by the power control blocks, for the loads at the output network of the first UPS. AC current is injected into the output network of the first UPS, by the power control blocks, based on the detecting and the datacenter power policy. The injecting does not disturb a voltage supplied by an upstream source. The injecting does not disturb a phase of AC frequency supplied by an upstream source.

The system 1300 can include one or more processors 1310 and a memory 1312 which stores instructions. The memory 1312 is coupled to the one or more processors 1310, wherein the one or more processors 1310 can execute instructions stored in the memory 1312. The memory 1312 can be used for storing instructions; for storing databases of power sources, power caches, and power loads; for storing information pertaining to load requirements or redundancy requirements; for storing power policies; for storing service level agreements; for system support; and the like. Information regarding datacenter power management using current injection can be shown on a display 1314 connected to the one or more processors 1310. The display can comprise a television monitor, a projector, a computer monitor (including a laptop screen, a tablet screen, a netbook screen, and the like), a smartphone display, a mobile device, or another electronic display.

The system 1300 can implement a computer system for power management comprising: a memory which stores instructions; one or more processors coupled to the memory wherein the one or more processors, when executing the instructions which are stored, are configured to: access a datacenter topology that includes at least one utility grid feed, one or more power caches, one or more power control blocks, one or more loads, and one or more uninterruptible power supplies (UPSs) providing AC power; allocate a supply capacity from a first UPS to the one or more loads within the datacenter topology, wherein the supply capacity is allocated below a peak load requirement for the one or more loads; detect an AC current requirement, by the one or more power control blocks, for the one or more loads at an output network of the first UPS; and inject AC current into the output network of the first UPS, by the one or more power control blocks, wherein the injecting is based on the AC current requirement that was detected.

The system 1300 includes allocation policies 1320. The allocation polices can include power policies, dynamic power policies, service level agreements, and so on. In embodiments, the allocation policies 1320 are stored in a networked database, such as a structured query language (SQL) database. The allocation policies 1320 can include limits, such as power consumption limits, as well as switch configurations when certain conditions are met. For example, when conditions allow peak shaving to take place, and surplus power exists, the power policies can identify switches and their configurations, which allow replenishing of one or more power caches. The system 1300 further includes a repository of power descriptions 1330. The power descriptions 1330 can include, but are not limited to, power descriptions of power loads, power caches, power supplies, rack power profiles, batteries, buses, circuit breakers, fuses, and the like. The power descriptions can include physical space needs, electrical equipment cooling requirements, etc. The system 1300 can include an implementing component 1340. The implementing component 1340 can be used for implementing a datacenter power policy. The datacenter power policy can oversee a datacenter topology. The datacenter topology can include at least one utility grid feed, one or more power caches, one or more power control blocks, one or more loads, one or more uninterruptible power supplies (UPSs), and backup power sets such as diesel-generator sets, etc., that can provide AC power. The one or more uninterruptible power supplies can include distributed UPSs, where the distributed UPSs can include associated UPSs distributed throughout a datacenter. The distributed UPSs can include UPS elements placed within data racks of IT racks. In embodiments, one or more of the UPSs can be replaced with one or more power caches. The datacenter power policy can be based on available power sources such as grid power, diesel-generator power, or alternative energy sources; battery backup capabilities; and so on. The datacenter power policy can be based on power source availability, power costs, contractual arrangements, etc.

The system 1300 includes an allocating component 1350. The allocating component 1350 is configured to allocate a supply capacity from a first UPS to the one or more loads within the datacenter. The supply capacity can be allocated below a peak load requirement for the one or more loads. The supply capacity can be allocated below a threshold load requirement. The supply capacity can be allocated based on the datacenter power policy. The allocating can be performed on computing equipment such as a local server, a remote server, a cloud-based server, a mesh server, and the like. The system 1300 includes a detecting component 1360. The detecting component 1360 can detect an AC current requirement, by the one or more power control blocks, for the one or more loads at the output network of the first UPS. An AC current requirement can represent an aggregate current requirement for various types of electrical equipment within a datacenter. The electrical equipment can include processors; servers; blade servers; communication equipment; heating, cooling, and air conditioning (HVAC) equipment; etc. The AC current requirement can include a timeframe during which the AC current can be provided. The system 1300 includes an injecting component 1370. The injecting component 1370 can inject AC current into the output network of the first UPS, by the one or more power control blocks, based on the detecting and the datacenter power policy. The injecting AC current can include AC current inverted from DC power stored in batteries or capacitors. In embodiments, the AC current that is injected by the one or more power control blocks can be sourced by at least one of the one or more power caches. In embodiments, the injecting does not disturb a voltage supplied by an upstream source. In embodiments, the injecting does not disturb a phase of AC frequency supplied by an upstream source. The injecting can be controlled using one or more modulation techniques. In embodiments, the injecting can be controlled using pulse width modulation (PWM).

Disclosed embodiments include a computer program product embodied in a non-transitory computer readable medium for power management, the computer program product comprising code which causes one or more processors to perform operations of: accessing a datacenter topology that includes at least one utility grid feed, one or more power caches, one or more power control blocks, one or more loads, and one or more uninterruptible power supplies (UPSs) providing AC power; allocating a supply capacity from a first UPS to the one or more loads within the datacenter topology, wherein the supply capacity is allocated below a peak load requirement for the one or more loads; detecting an AC current requirement, by the one or more power control blocks, for the one or more loads at an output network of the first UPS; and injecting AC current into the output network of the first UPS, by the one or more power control blocks, wherein the injecting is based on the AC current requirement that was detected.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagrams and flowchart illustrations depict methods, apparatus, systems, and computer program products. The elements and combinations of elements in the block diagrams and flow diagrams, show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited neither to conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM), an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A computer-implemented method for power management comprising:
accessing a datacenter topology that includes at least one utility grid feed, one or more power caches, one or more power control blocks, one or more loads, and one or more uninterruptible power supplies (UPSs) providing AC power;
allocating a supply capacity from a first UPS to the one or more loads within the datacenter topology, wherein the supply capacity is allocated below a peak load requirement for the one or more loads;
detecting an AC current requirement, by the one or more power control blocks, for the one or more loads at an output network of the first UPS; and
injecting AC current into the output network of the first UPS, by the one or more power control blocks, wherein the injecting is based on the AC current requirement that was detected.

2. The method of claim 1 wherein the injecting does not disturb a voltage supplied by an upstream source.

3. The method of claim 1 wherein the injecting does not disturb a phase of AC frequency supplied by an upstream source.

4. The method of claim 1 wherein the AC current that is injected by the one or more power control blocks is sourced by at least one of the one or more power caches.

5. The method of claim 1 wherein the injecting is controlled using pulse width modulation.

6. The method of claim 5 wherein the pulse width modulation is enabled by one or more current mode grid tie inverters.

7. The method of claim 5 wherein the pulse width modulation is used to control output of at least one of the one or more power caches.

8. The method of claim 1 further comprising injecting AC current into the output network of a second UPS of the one or more UPSs.

9. The method of claim 8 wherein the second UPS is sourced from a different utility grid source from the first UPS.

10. The method of claim 8 wherein the second UPS provides datacenter power redundancy.

11. The method of claim 1 further comprising implementing a datacenter power policy that controls the datacenter topology.

12. The method of claim 11 wherein the supply capacity is allocated based on the datacenter power policy.

13. The method of claim 11 further comprising issuing the datacenter power policy to individual hardware components within the datacenter topology.

14. The method of claim 13 wherein the issuing enables the individual hardware components to inject current into the output network, based on the datacenter power policy.

15. The method of claim 1 wherein the injecting enables using redundant power from two utility feeds in a 2N system to increase power available to the datacenter topology.

16. The method of claim 1 further comprising predicting an amount of AC current for injecting into the output network using a software-based datacenter model.

17. The method of claim 1 wherein the one or more loads within the datacenter topology are mission critical loads.

18. The method of claim 1 wherein the allocating and the injecting are based on a datacenter power policy.

19. The method of claim 18 further comprising updating the datacenter power policy, based on additional source and load data.

20-23. (canceled)

24. The method of claim 1 wherein the datacenter topology includes utility power sources and local power feed components.

25. The method of claim 24 wherein the local power feed components include renewable power sources.

26. The method of claim 1 wherein the datacenter topology provides a series connection from the first UPS to two or more datacenter racks.

27. The method of claim 1 wherein the datacenter topology provides a parallel connection from the first UPS to two or more datacenter racks.

28. The method of claim 1 wherein at least one of the one or more uninterruptible power supplies is operated in pass-through mode.

29. A computer program product embodied in a non-transitory computer readable medium for power management, the computer program product comprising code which causes one or more processors to perform operations of:
accessing a datacenter topology that includes at least one utility grid feed, one or more power caches, one or more power control blocks, one or more loads, and one or more uninterruptible power supplies (UPSs) providing AC power;
allocating a supply capacity from a first UPS to the one or more loads within the datacenter topology, wherein the supply capacity is allocated below a peak load requirement for the one or more loads;
detecting an AC current requirement, by the one or more power control blocks, for the one or more loads at an output network of the first UPS; and
injecting AC current into the output network of the first UPS, by the one or more power control blocks, wherein the injecting is based on the AC current requirement that was detected.

30. A computer system for power management comprising:
a memory which stores instructions;
one or more processors coupled to the memory wherein the one or more processors, when executing the instructions which are stored, are configured to:
access a datacenter topology that includes at least one utility grid feed, one or more power caches, one or more power control blocks, one or more loads, and one or more uninterruptible power supplies (UPSs) providing AC power;
allocate a supply capacity from a first UPS to the one or more loads within the datacenter topology, wherein the supply capacity is allocated below a peak load requirement for the one or more loads;
detect an AC current requirement, by the one or more power control blocks, for the one or more loads at an output network of the first UPS; and
inject AC current into the output network of the first UPS, by the one or more power control blocks, wherein the injecting is based on the AC current requirement that was detected.
